(19) United States
(12) Patent Application Publication
(10) Pub. No.: US 2024/0379898 A1
(43) Pub. Date: Nov. 14, 2024

(54) Method of Manufacturing Display Device

(71) Applicant: LG Display Co, Ltd., Seoul (KR)

(72) Inventors: ChungHwan An, Goyang-si (KR); Eunjeong Shin, Paju-si (KR)

(21) Appl. No.: 18/647,168

(22) Filed: Apr. 26, 2024

(30) Foreign Application Priority Data
May 12, 2023 (KR) 10-2023-0061545

(51) Int. Cl. H01L 33/00; H01L 25/075

(52) U.S. Cl. CPC H01L 33/005; H01L 25/0753

(57) ABSTRACT

A method of manufacturing a display device is disclosed. The method comprises
aligning a first wafer with a donor substrate, the first wafer including a first light emitting diodes (LEDs), first alignment keys, and second alignment keys. The method comprises transferring the first LEDs and a portion of the second alignment keys included in the first wafer onto the donor substrate. The method comprises aligning a second wafer with the donor substrate, the second wafer including second LEDs, first alignment keys, second alignment keys, and third alignment keys of the second wafer. The second wafer is aligned with the donor substrate by aligning the portion of the second alignment keys of the first wafer that are disposed on the donor substrate with the third alignment keys of the second wafer.

### CROSS-REFERENCE TO RELATED APPLICATION

This application claims the priority of Republic of Korea Patent Application No. 10-2023-0061545 filed on May 12, 2023, in the Korean Intellectual Property Office, which is hereby incorporated by reference in its entirety.

### BACKGROUND

### Field

The present disclosure relates to a method of manufacturing a display device, and more particularly, to a method of manufacturing a display device with an improved alignment accuracy of a plurality of light emitting diodes (LEDs).

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to provide a method of manufacturing a display device with an improved alignment accuracy of a plurality of LEDs in a primary transfer process and a secondary transfer process. The primary transfer process is performed to transfer the plurality of LEDs to a donor substrate from a wafer. The secondary transfer process is performed to transfer the plurality of LEDs to a display panel from the donor substrate.

Another object to be achieved by the present disclosure is to provide a method of manufacturing a display device with an improved alignment accuracy of a plurality of LEDs without limitation to the size of the plurality of LEDs.

Yet another object to be achieved by the present disclosure is to provide a method of manufacturing a display device with reduced process time and cost by shortening time required for a secondary transfer process. In the secondary transfer process, a red LED, a green LED, and a blue LED corresponding to a plurality of sub pixels, respectively, are transferred to a display panel at a time.

Still another object to be achieved by the present disclosure is to provide a method of manufacturing a display device with improved productivity and yield by simplifying a primary transfer process and a secondary transfer process and precisely aligning a plurality of LEDs.

Still another object to be achieved by the present disclosure is to provide a wafer in which an additional alignment key is disposed, which may minimize alignment and transfer error ranges and a distribution/spread of a plurality of LEDs.

Objects of the present disclosure are not limited to the above-mentioned objects, and other objects, which are not mentioned above, can be clearly understood by those skilled in the art from the following descriptions.

In one embodiment, a method of manufacturing a display device comprises: aligning a first wafer with a donor substrate, the first wafer including a plurality of first light emitting diodes (LEDs), a plurality of first alignment keys, and a plurality of second alignment keys; transferring the plurality of first LEDs and a portion of the plurality of second alignment keys included in the first wafer onto the donor substrate; and aligning a second wafer with the donor substrate, the second wafer including a plurality of second LEDs, a plurality of first alignment keys, a plurality of second alignment keys, and a plurality of third alignment keys, wherein the second wafer is aligned with the donor substrate by aligning the portion the plurality of second alignment keys of the first wafer that are disposed on the donor substrate with the plurality of third alignment keys of the second wafer.

In one embodiment, a wafer comprises: an active area and a peripheral area enclosing the active area; a plurality of light emitting diodes (LEDs) in the active area but not the peripheral area; and a plurality of alignment keys in the peripheral area but not the active area, the plurality of alignment keys including a plurality of first alignment keys having a first size, a plurality of second alignment keys having a second size that is different from the first size, and a plurality of third alignment keys having a third size that is different from the first size and the second size.

In one embodiment, a method of manufacturing a display device comprises: placing a first wafer over a donor substrate, the first wafer including a plurality of first light emitting diodes (LEDs) that are configured to emit a first color of light, a plurality of first alignment keys, and a plurality of second alignment keys, and the donor substrate including a plurality of first alignment protrusions and a plurality of second alignment protrusions; aligning each of the plurality of first alignment keys of the first wafer with a corresponding first alignment protrusion from the plurality of first alignment protrusions; transferring the plurality of first LEDs and a subset of the plurality of second alignment keys included in the first wafer onto the donor substrate after the alignment of each of the plurality of first alignment keys of the first wafer with the corresponding first alignment protrusion from the plurality of first protrusions, the subset of the plurality of second alignment keys transferred to the plurality of second alignment protrusions on the donor substrate; placing a second wafer over the donor substrate including the plurality of first LEDs and the subset of the plurality of second alignment keys from the first wafer, the second wafer including a plurality of second LEDs that are configured to emit a second color of light that is different from the first color of light and a plurality of alignment keys; aligning each second alignment key from the subset of the plurality of second alignment keys that were transferred from the first wafer to the donor substrate with a corresponding one of the plurality of alignment keys of the second wafer; shifting the second wafer by a first interval that corresponds to a distance between a pair of second LEDs from the plurality of second LEDs on the second wafer after aligning each second alignment key with the corresponding one of the plurality of alignment keys of the second wafer; and transferring the plurality of second LEDs onto the donor substrate without transferring any of the plurality of alignment keys of the second wafer onto the donor substrate after shifting the second wafer by the first interval.

Other detailed matters of the exemplary embodiments are included in the detailed description and the drawings.

According to the present disclosure, a plurality of ultrafine-sized LEDs may be easily aligned.

According to the present disclosure, a decrease in yield caused by an alignment error in a process of transferring a plurality of LEDs may be minimized.

According to the present disclosure, time required for a primary transfer process and a secondary transfer process is shortened. Thus, the process time and cost for manufacturing a display device may be reduced and the productivity may be improved.

According to the present disclosure, an additional alignment key is disposed in a wafer. Thus, the alignment and transfer accuracy of the plurality of LEDs may be improved.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic configuration diagram of a display device according to an exemplary embodiment of the present disclosure;

FIG. 2A is a partial cross-sectional view of the display device according to an exemplary embodiment of the present disclosure;

FIG. 2B is a perspective view of a tiling display device according to an exemplary embodiment of the present disclosure;

FIG. 3A is a plan view of a display panel before grinding of the display device according to an exemplary embodiment of the present disclosure;

FIG. 3B is a plan view of the display panel after grinding of the display device according to an exemplary embodiment of the present disclosure;

FIG. 4A and FIG. 4B are plan views of a pixel area of the display device according to an exemplary embodiment of the present disclosure;

FIG. 5 is a cross-sectional view of the pixel area of the display device according to an exemplary embodiment of the present disclosure;

FIG. 6 is a process flowchart for explaining a method of manufacturing a display device according to an exemplary embodiment of the present disclosure;

FIG. 7A through FIG. 7L are schematic process diagrams for explaining the method of manufacturing a display device according to an exemplary embodiment of the present disclosure and a wafer according to an exemplary embodiment of the present disclosure; and

FIG. 8 is a process diagram for explaining the method of manufacturing a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a method of manufacturing a display device and a wafer according to exemplary embodiments of the present disclosure will be described in detail with reference to accompanying drawings.

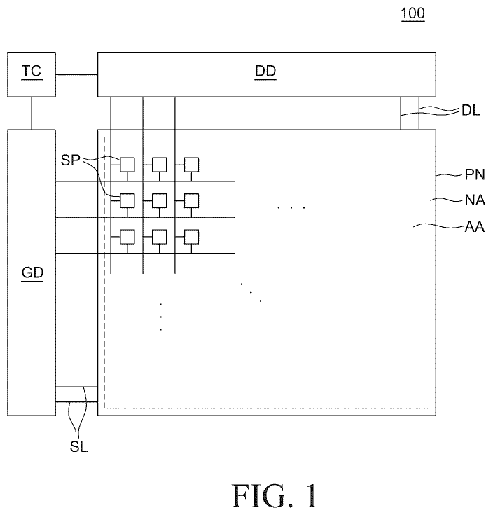

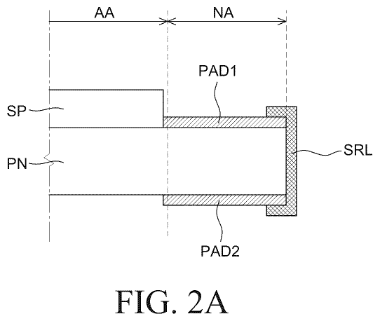

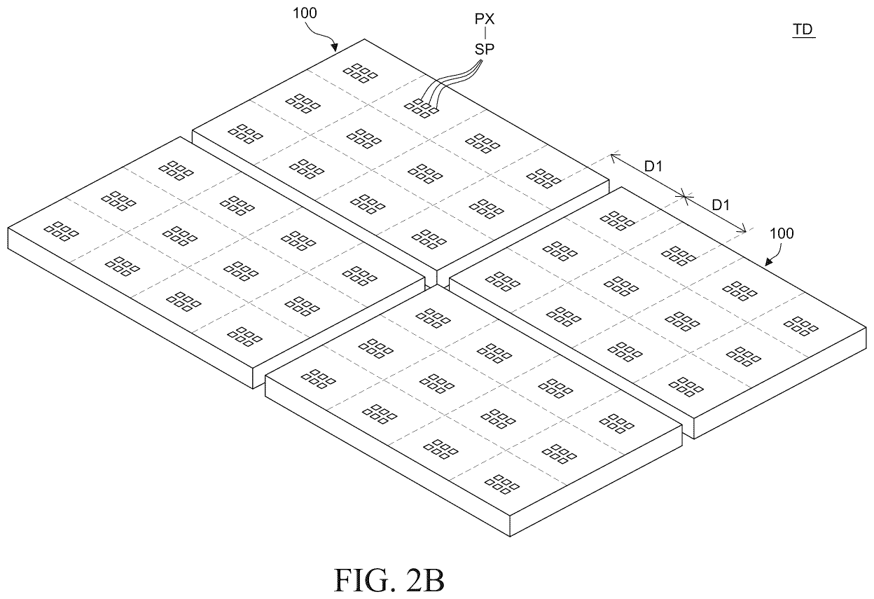

FIG. 1 is a schematic configuration diagram of a display device according to an exemplary embodiment of the present disclosure. FIG. 2A is a partial cross-sectional view of the display device according to an exemplary embodiment of the present disclosure. FIG. 2B is a perspective view of a tiling display device according to an exemplary embodiment of the present disclosure. FIG. 1 illustrates only a display panel PN, a gate driver GD, a data driver DD, and a timing controller TC among various components of a display device 100 for convenience in explanation.

Referring to FIG. 1, the display device 100 includes the display panel PN including a plurality of sub pixels SP, and the gate driver GD and the data driver DD for supplying various signals to the display panel PN. The display device 100 also includes the timing controller TC for controlling the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN, but the number and disposition of gate drivers GD are not limited thereto.

The data driver DD converts image data input from the timing controller TC into a data voltage using a reference gamma voltage according to a plurality of data control signals supplied from the timing controller TC. Also, the data driver DD may supply the converted data voltage to a plurality of data lines DL.

The timing controller TC aligns the image data input from the outside and supplies the image data to the data driver DD. The timing controller TC may generate gate control signals and data control signals using synchronization signals input from the outside, e.g., a dot clock signal, a data enable signal, and a horizontal/vertical synchronization signal. Also, the timing controller TC may supply the generated gate control signals and data control signals to the gate driver GD and the data driver DD, respectively, and thus may control the gate driver GD and the data driver DD.

The display panel PN is configured to display images to a user and includes the plurality of sub pixels SP. In the display panel PN, the plurality of scan lines SL and the plurality of data lines DL intersect each other, and each of the plurality of sub pixels SP is connected to the scan line SL and the data line DL. In addition, although not illustrated in the drawings, each of the plurality of sub pixels SP may be connected to a high potential power line, a low potential power line, a reference line, and the like.

In the display panel PN, a display area AA and a non-display area NA enclosing the display area AA may be defined.

The display area AA is an area in which images are displayed in the display device 100. In the display area AA, a plurality of sub pixels SP constituting a plurality of pixels PX and a circuit for driving the plurality of sub pixels SP may be disposed. The plurality of sub pixels SP may represent a minimum unit of the display area AA. N number of sub pixels SP may form one pixel. In each sub pixel SP, a light emitting diode (LED) and a thin film transistor for driving the LED may be disposed. The plurality of LEDs may be differently defined depending on the type of the display panel PN. For example, when the display panel PN is an inorganic light emitting display panel, the LED may be a light emitting diode or a micro light emitting diode (micro LED).

In the display area AA, a plurality of lines for transmitting various signals to the plurality of sub pixels SP are disposed. For example, the plurality of lines may include a plurality of data lines DL for supplying a data voltage to the plurality of sub pixels SP, respectively. Also, the plurality of lines may include a plurality of scan lines SL for supplying a scan signal to the plurality of sub pixels SP, respectively. The plurality of scan lines SL may extend in one direction in the display area AA and may be connected to the plurality of sub pixels SP. Further, the plurality of data lines DL may extend in a different direction from the one direction in the display area AA and may be connected to the plurality of sub pixels SP. A low potential power line, a high potential power line, etc. may be further disposed in the display area AA. However, the present disclosure is not limited thereto.

The non-display area NA is an area in which no image is displayed, and may be defined as an area extending from the display area AA. In the non-display area NA, a link line and a pad electrode for transmitting signals to the sub pixels SP disposed in the display area AA, and driver ICs such as a gate driver IC and a data driver IC may be disposed.

However, the non-display area NA may be located on a rear surface of the display panel PN, that is, a surface on which the sub pixels SP are not disposed, or may be omitted and is not limited to the example illustrated in the drawing.

Meanwhile, a driving unit including the gate driver GD, the data driver DD, and the timing controller TC may be connected to the display panel PN in various ways. For example, the gate driver GD may be mounted in the non-display area NA as a GIP (Gate In Panel), or mounted between the plurality of sub pixels SP in the display area AA as a GIA (Gate In Active area). For example, the data driver DD and the timing controller TC may be provided on a separate flexible film and a printed circuit board (PCB). Also, the data driver DD and the timing controller TC may be electrically connected to the display panel PN by bonding the flexible film and the PCB to the pad electrode disposed in the non-display area NA of the display panel PN.

The gate driver GD may be mounted as the GIP, and the data driver DD and the timing controller TC may transmit a signal to the display panel PN through the pad electrode disposed in the non-display area NA. In this case, the non-display area NA requires a predetermined area for placing the gate driver GD and the pad electrode, and, thus, a bezel may increase.

However, the gate driver GD may be mounted in the display area AA as the GIA, and a side line SRL for connecting a signal line on a front surface of the display panel PN to the pad electrode on the rear surface of the display panel PN may be provided and the flexible film and the PCB may be bonded to the rear surface of the display panel PN. In this case, the non-display area NA may be minimized on the front surface of the display panel PN. That is, when the gate driver GD, the data driver DD, and the timing controller TC are connected to the display panel PN as described above, a zero bezel where there is virtually no bezel may be implemented.

Specifically, referring to FIG. 2A and FIG. 2B, a plurality of pad electrodes PAD1 and PAD2 for transmitting various signals to the plurality of sub pixels SP are disposed in the non-display area NA of the display panel PN. For example, a plurality of first pad electrodes PAD1 for transmitting signals to the plurality of sub pixels SP are disposed in the non-display area NA on the front surface of the display panel PN. Also, a plurality of second pad electrodes PAD2 electrically connected to driving components such as the flexible film and the PCB are disposed in the non-display area NA on the rear surface of the display panel PN. That is, only a pad area in which the first pad electrodes PAD1 are disposed in the non-display area NA may be formed to a minimum size on the front surface of the display panel PN in which the image is displayed.

In this case, although not illustrated in the drawings, various signal lines, e.g., the scan lines SL or data lines DL, connected to the plurality of sub pixels SP may extend from the display area AA to the non-display area NA and then may be electrically connected to the first pad electrodes PAD1.

Further, the side line SRL is disposed along a side surface of the display panel PN. The side line SRL may serve to electrically connect the first pad electrodes PAD1 on the front surface of the display panel PN to the second pad electrodes PAD2 on the rear surface of the display panel PN. Thus, signals from the driving components disposed on the rear surface of the display panel PN may be transmitted to the plurality of sub pixels SP through the second pad electrodes PAD2, the side line SRL, and the first pad electrodes PAD1. Therefore, a signal transmission path is formed from the front surface to the side and rear surfaces of the display panel PN, and, thus, the size of the non-display area NA on the front surface of the display panel PN may be minimized.

Further, referring to FIG. 2B, a tiling display device TD having a large size screen may be implemented by connecting a plurality of display devices 100. In this case, if the tiling display device TD is implemented by using the display devices 100 each having a minimized bezel as shown in FIG. 2A, a seam where no image is displayed may be minimized between adjacent display devices 100. Therefore, the display quality may be improved.

For example, the plurality of sub pixels SP may form one pixel PX, and an interval D1 between an outermost pixel PX of one display device 100 and an outermost pixel PX of another adjacent display device 100 may be designed to be equal to an interval D1 between pixels PX in one display device 100. Therefore, the interval D1 between pixels PX is constant between the display devices 100, and, thus, the seam may be minimized or at least reduced.

However, the configuration shown in FIG. 2A and FIG. 2B is exemplary, and the display device according to the exemplary embodiment of the present disclosure may be a typical display device having a bezel, but is not limited thereto.

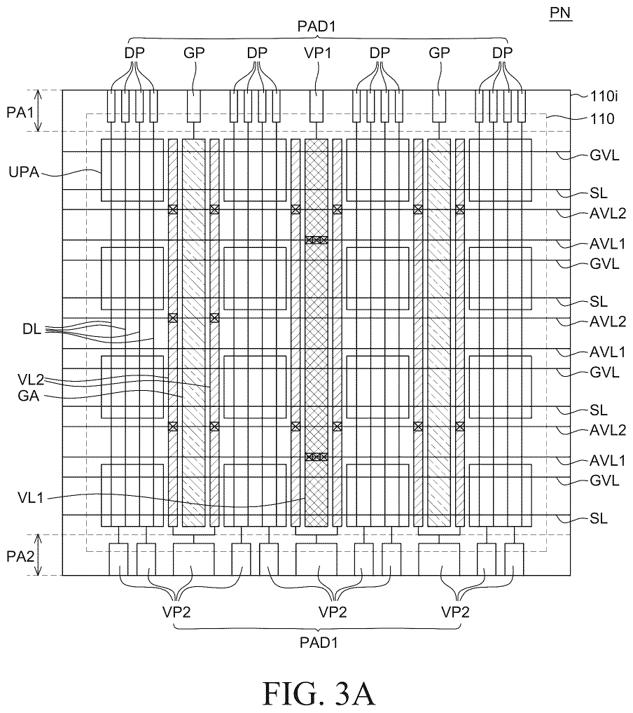

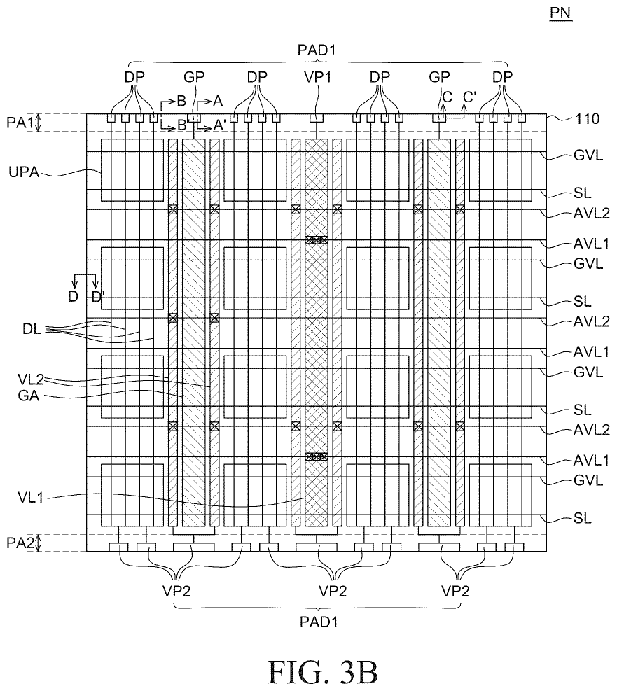

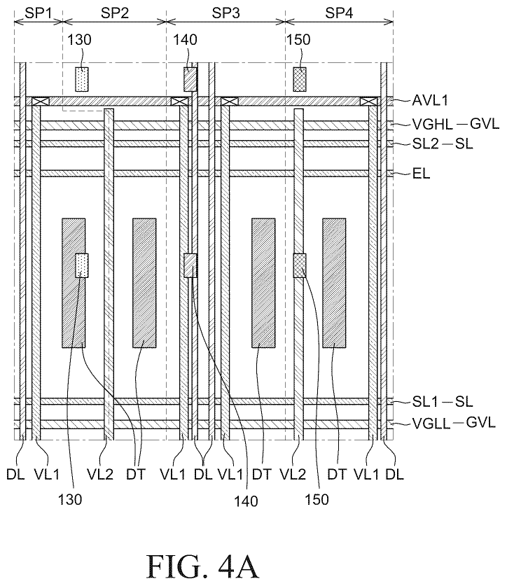

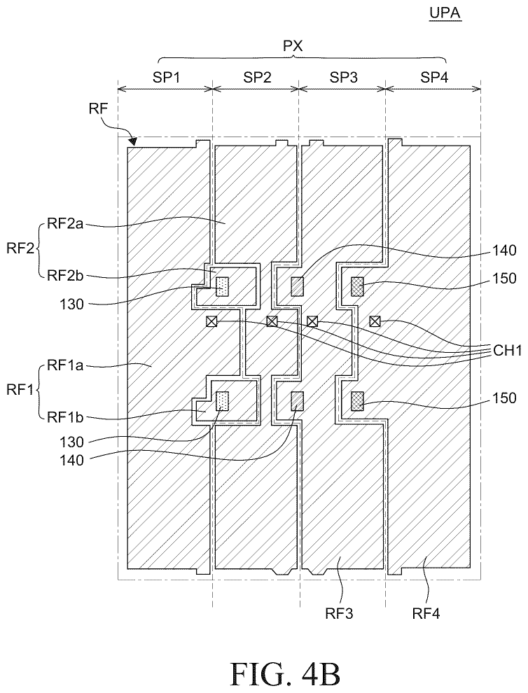

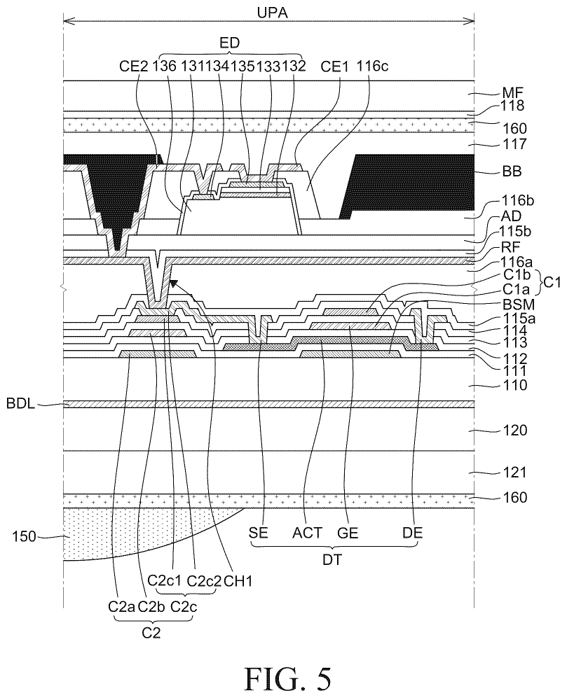

FIG. 3A is a plan view of a display panel before grinding of the display device according to an exemplary embodiment of the present disclosure. FIG. 3B is a plan view of the display panel after grinding of the display device according to an exemplary embodiment of the present disclosure. FIG. 4A and FIG. 4B are plan views of a pixel area of the display device according to an exemplary embodiment of the present disclosure. FIG. 5 is a cross-sectional view of the pixel area of the display device according to an exemplary embodiment of the present disclosure. FIG. 4A illustrates only a plurality of LEDs ED, a driving transistor DT of a pixel circuit, and a plurality of lines, and FIG. 4B illustrates only a plurality of reflective sheets RF and the plurality of LEDs ED.

First, referring to FIG. 3A through FIG. 5, the display panel PN includes a first substrate 110. The first substrate 110 serves to support components disposed on the display device 100, and may be an insulating substrate. A plurality of pixels PX may be provided on the first substrate 110 to display images. For example, the first substrate 110 may be made of glass or resin. Further, the first substrate 110 may also contain a polymer or plastic. In some exemplary embodiments, the first substrate 110 may be made of a plastic material having flexibility.

Referring to FIG. 3A and FIG. 3B, a plurality of pixel areas UPA, a plurality of gate driving areas GA, and a plurality of pad areas are disposed in the first substrate 110. The plurality of pixel areas UPA and the plurality of gate driving areas GA may be included in the display area AA of the display panel PN.

First, in the plurality of pixel areas UPA, the plurality of pixels PX are disposed. The plurality of pixel areas UPA may be disposed in a plurality of rows and a plurality of columns. Each of the plurality of pixels PX disposed in the plurality of pixel areas UPA includes the plurality of sub pixels SP. Each of the plurality of sub pixels SP includes a LED ED and a pixel circuit and thus may independently emit light.

In the plurality of gate driving areas GA, the gate driver GD is disposed. The gate driver GD may be mounted in the display area AA as the GIA. For example, the gate driving areas GA may be provided in a row direction and/or a column direction between the plurality of pixel areas UPA. The gate driver GD disposed in the gate driving areas GA may supply scan signals to the plurality of scan lines SL.

The gate driver GD disposed in the gate driving areas GA may include a circuit configured to output scan signals. In this case, the gate driver GD may include, e.g., a plurality of transistors and/or a capacitor. Herein, active layers of the plurality of transistors may be made of semiconductor materials, such as oxide semiconductor, amorphous silicon, or polysilicon, but is not limited thereto. In this case, the active layers of the plurality of transistors may be made of the same material, or may be made of different materials from each other. Also, the active layers of the transistors in the gate driver GD may be made of the same material as active layers of various transistors in the pixel circuit, or may be made of different materials from each other.

In the plurality of pad areas, the plurality of first pad electrodes PAD1 are disposed. The plurality of first pad electrodes PAD1 may serve to transmit various signals to various lines extending in the column direction in the display area AA. For example, the plurality of first pad electrodes PAD1 includes a data pad DP for transmitting a data voltage to the data line DL and a gate pad GP for transmitting a clock signal, a start signal, a gate low voltage, a gate high voltage, etc. for driving the gate driver GD to the gate driver GD. Also, the plurality of first pad electrodes PAD1 includes a high potential power pad VP1 for transmitting a high potential power voltage to a high potential power line VL1 and a low potential power pad VP2 for transmitting a low potential power voltage to a low potential power line VL2.

The plurality of pad areas include a first pad area PA1 located at an upper edge of the display panel PN and a second pad area PA2 of the display panel PN. Herein, different types of first pad electrodes PAD1 may be disposed in the first pad area PA1 and the second pad area PA2. For example, the data pad DP, the gate pad GP, and the high potential power pad VP1 among the plurality of first pad electrodes PAD1 may be disposed in the first pad area PA1, and the low potential power pad VP2 may be disposed in the second pad area PA2.

In this case, the plurality of first pad electrodes PAD1 may be formed to have different sizes from each other. For example, a plurality of data pads DP connected to the plurality of data lines DL, respectively, may have a relatively smaller width, and the high potential power pad VP1, the low potential power pad VP2 and the gate pad GP may have a relatively greater width. However, the widths of the data pad DP, the gate pad GP, the high potential power pad VP1, and the low potential power pad VP2 shown in FIG. 3A and FIG. 3B are exemplary. The first pad electrodes PAD1 may have various sizes, and the present disclosure is not limited thereto.

Meanwhile, an edge of the display panel PN may be cut off and removed to reduce a bezel of the display panel PN. For example, the plurality of pixels PX, the plurality of lines, and the plurality of first pad electrodes PAD1 may be provided on an initial first substrate 110i as shown in FIG. 3A. Also, an edge of the initial first substrate 110i may be ground to reduce the bezel as shown in FIG. 3B. In the grinding process, a part of the initial first substrate 110i may be removed, and, thus, the first substrate 110 having a smaller size may be prepared. In this case, parts of the plurality of first pad electrodes PAD1 and lines disposed in the edge of the first substrate 110 may be removed. Therefore, only the other parts of the plurality of first pad electrodes PAD1 may remain on the first substrate 110.

Then, the plurality of data lines DL extending from the plurality of first pad electrodes PAD1 in the column direction is disposed on the first substrate 110 of the display panel PN. The plurality of data lines DL may extend from the plurality of data pads DP of the first pad area PA1 toward the plurality of pixel areas UPA. The plurality of data lines DL may extend in the column direction and may be disposed to overlap the plurality of pixel areas UPA. Thus, the plurality of data lines DL may transmit data voltages to the pixel circuit of the plurality of sub pixels SP, respectively.

A plurality of high potential power lines VL1 extending in the column direction are disposed on the first substrate 110 of the display panel PN. Some of the plurality of high potential power lines VL1 may extend from the high potential power pad VP1 of the first pad area PA1 toward the plurality of pixel areas UPA and thus may transmit high potential power voltages to the respective LEDs ED of the plurality of sub pixels SP. Also, the others of the plurality of high potential power lines VL1 may be electrically connected to other high potential power lines VL1 through auxiliary high potential power lines AVL1 to be described later. FIG. 3A and FIG. 3B illustrate one high potential power line VL1 and one high potential power pad VP1 for convenience in explanation. However, a plurality of high potential power lines VL1 and a plurality of high potential power pads VP1 may be provided.

A plurality of low potential power lines VL2 extending in the column direction are disposed on the first substrate 110 of the display panel PN. At least some of the plurality of low potential power lines VL2 may extend from the low potential power pad VP2 of the second pad area PA2 toward the plurality of pixel areas UPA and thus may transmit low potential power voltages to the respective pixel circuits of the plurality of sub pixels SP. Also, the others of the plurality of low potential power lines VL2 may be electrically connected to other low potential power lines VL2 through auxiliary low potential power lines AVL2 to be described later.

The plurality of scan lines SL extending in the row direction are disposed on the first substrate 110 of the display panel PN. The plurality of scan lines SL may extend in the row direction, and may be disposed to cross the plurality of pixel areas UPA and the plurality of gate driving areas GA. The plurality of scan lines SL may serve to transmit scan signals from the gate driver GD to the respective pixel circuits of the plurality of sub pixels SP.

A plurality of auxiliary high potential power lines AVL1 extending in the row direction are disposed on the first substrate 110 of the display panel PN. The plurality of auxiliary high potential power lines AVL1 may be disposed in a region between the plurality of pixel areas UPA. The plurality of auxiliary high potential power lines AVL1 extending in the row direction may be electrically connected to the plurality of high potential power lines VL1 extending in the column direction through contact holes to form a mesh structure. Thus, since the plurality of auxiliary high potential power lines AVL1 and the plurality of high potential power lines VL1 form a mesh structure, it is possible to minimize a voltage drop and a voltage difference.

A plurality of auxiliary low potential power lines AVL2 extending in the row direction are disposed on the first substrate 110 of the display panel PN. The plurality of auxiliary low potential power lines AVL2 may be disposed in a region between the plurality of pixel areas UPA. The plurality of auxiliary low potential power lines AVL2 extending in the row direction may be electrically connected to the plurality of low potential power lines VL2 extending in the column direction through contact holes to form a mesh structure. Thus, since the plurality of auxiliary low potential power lines AVL2 and the plurality of low potential power lines VL2 form a mesh structure, it is possible to reduce a line resistance and minimize a voltage difference.

Referring to FIG. 3A through FIG. 4A, a plurality of gate driving lines GVL extending in the row direction and the column direction is disposed on the first substrate 110 of the display panel PN. Some of the plurality of gate driving lines GVL may extend from the gate pad GP of the first pad area PA1 to the gate driving area GA and thus may transmit signals to the gate driver GD. The others of the plurality of gate driving lines GVL may extend in the row direction and thus may transmit signals to the gate driver GD of the plurality of gate driving areas GA. Thus, various signals may be transmitted from the gate driving lines GVL to the gate driver GD. Therefore, the gate driver GD may be driven.

The plurality of gate driving lines GVL may include lines for transmitting a clock signal, a start signal, a gate high voltage, a gate low voltage, etc. to the gate driver GD. Thus, various signals may be transmitted from the gate driving lines GVL to the gate driver GD. Therefore, the gate driver GD may be driven.

For example, referring to FIG. 4A, the plurality of gate driving lines GVL may include a gate power line for transmitting a power voltage to the gate driver GD of the gate driving area GA. A plurality of gate power lines may include a first gate power line VGHL for transmitting a gate high voltage to the gate driver GD and a second gate power line VGLL for transmitting a gate low voltage to the gate driver GD.

Hereinafter, the plurality of sub pixels SP of the pixel area UPA will be described in more detail with reference to FIG. 4A through FIG. 5.

Referring to FIG. 4A and FIG. 4B, the plurality of sub pixels SP forming one pixel PX are disposed in one pixel area UPA. For example, the plurality of sub pixels SP may include a first sub pixel SP1, a second sub pixel SP2, a third sub pixel SP3 and a fourth sub pixel SP4 which emit light of different colors from each other. For example, the first sub pixel SP1 and the second sub pixel SP2 may be red sub pixels SP, the third sub pixel SP3 may be a green sub pixel SP, and the fourth sub pixel SP4 may be a blue sub pixel SP. However, the present disclosure is not limited thereto.

Referring to FIG. 4A, a plurality of lines for supplying various signals to the plurality of sub pixels SP is disposed in the plurality of pixel areas UPA of the first substrate 110 as described above. For example, the plurality of data lines DL, the plurality of high potential power lines VL1 and the plurality of low potential power lines VL2 extending in the column direction may be disposed on the first substrate 110. For example, a plurality of emission control signal lines EL, the plurality of auxiliary high potential power lines AVL1, the plurality of auxiliary low potential power lines AVL2, a plurality of first scan lines SL1 and a plurality of second scan lines SL2 extending in the row direction may be disposed on the first substrate 110. Further, the high potential power lines VL1 extending in the column direction may be electrically connected to each other through the auxiliary high potential power line AVL1 extending in the row direction and the contact hole. Herein, the emission control signal lines EL may transmit emission control signals to the respective pixel circuits of the plurality of sub pixels SP. Thus, it is possible to control emission timing of each of the plurality of sub pixels SP.

Further, some of the gate driving lines GVL for transmitting signals to the plurality of gate drivers GD spaced apart from each other with the pixel area UPA interposed therebetween may extend in the row direction, and may be disposed to cross the pixel area UPA. For example, the first gate power line VGHL for supplying a gate high voltage to the gate driver GD and the second gate power line VGLL for supplying a gate low voltage to the gate driver GD may be disposed to cross the pixel area UPA.

Meanwhile, it is illustrated that the plurality of scan lines SL includes the first scan lines SL1 and the second scan lines SL2. However, the configuration of the plurality of scan lines SL is not limited thereto, and may vary depending on the configuration of the pixel circuit of the sub pixel SP.

The pixel circuit for driving the LED ED is disposed in each of the plurality of sub pixels SP on the first substrate 110. The pixel circuit may include a plurality of thin film transistors and a plurality of capacitors. FIG. 4A and FIG. 5 illustrate only a driving transistor DT, a first capacitor C1, and a second capacitor C2 among the components of the pixel circuit for convenience in explanation. However, the pixel circuit may further include a switching transistor, a sensing transistor, an emission control transistor, etc., but is not limited thereto.

First, a light shielding layer BSM is disposed on the first substrate 110. The light shielding layer BSM may serve to block light incident into an active layer ACT of a plurality of transistors and minimize a leakage current. For example, the light shielding layer BSM may be disposed under the active layer ACT of the driving transistor DT to block light incident into the active layer ACT. When light is irradiated to the active layer ACT, a leakage current may occur, and, thus, the reliability of the transistor may be degraded. Therefore, the light shielding layer BSM configured to block light may be disposed on the first substrate 110 to improve the reliability of the driving transistor DT. The light shielding layer BSM may be made of an opaque conductive material, such as copper (Cu), aluminum (Al), molybdenum (Mo), nickel (Ni), titanium (Ti), chrome (Cr) or an alloy thereof, but is not limited thereto.

A buffer layer 111 is disposed on the light shielding layer BSM. The buffer layer 111 may serve to suppress the permeation of moisture or impurities through the first substrate 110. The buffer layer 111 may be configured by a single layer of, for example, silicon oxide (SiOx) or silicon nitride (SiNx) or a multi-layer thereof, but is not limited thereto. However, the buffer layer 111 may be omitted depending on the type of the first substrate 110 or the type of the thin film transistor, but is not limited thereto.

The driving transistor DT including the active layer ACT, a gate electrode GE, a source electrode SE, and a drain electrode DE is disposed on the buffer layer 111.

Meanwhile, although not illustrated in FIG. 5, an additional buffer layer may be disposed between the first substrate 110 and the light shielding layer BSM. Like the buffer layer 111, the additional buffer layer may be configured by a single layer of, for example, silicon oxide (SiOx) or silicon nitride (SiNx) or a multi-layer thereof to suppress the permeation of moisture or impurities through the first substrate 110, but is not limited thereto.

First, the active layer ACT of the driving transistor DT is disposed on the buffer layer 111. The active layer ACT may be made of a semiconductor material, such as oxide semiconductor, amorphous silicon, or polysilicon, but is not limited thereto. Further, although not illustrated in the drawings, other transistors, such as a switching transistor, a sensing transistor, an emission control transistor, etc., besides the driving transistor DT may be further provided. Active layers of these transistors may also be made of semiconductor materials, such as oxide semiconductor, amorphous silicon, or polysilicon, but are not limited thereto. Also, the active layers of the transistors, such as the driving transistor DT, the switching transistor, the sensing transistor, the emission control transistor, etc., included in the pixel circuit may be made of the same material, or may be made of different materials from each other.

A gate insulating layer 112 is disposed on the active layer ACT. The gate insulating layer 112 serves to electrically insulate the active layer ACT from the gate electrode GE. The gate insulating layer 112 may be configured by a single layer of silicon oxide (SiOx) or silicon nitride (SiNx) or a multi-layer thereof, but is not limited thereto.

The gate electrode GE is disposed on the gate insulating layer 112. The gate electrode GE may be made of a conductive material, such as copper (Cu), aluminum (Al), molybdenum (Mo), nickel (Ni), titanium (Ti), chrome (Cr) or an alloy thereof, but is not limited thereto.

A first interlayer insulating layer 113 and a second interlayer insulating layer 114 are disposed on the gate electrode GE. The first interlayer insulating layer 113 and the second interlayer insulating layer 114 includes contact holes for connecting the source electrode SE and the drain electrode DE, respectively, to the active layer ACT. The first interlayer insulating layer 113 and the second interlayer insulating layer 114 serve to protect the components disposed thereunder. Each of the first interlayer insulating layer 113 and the second interlayer insulating layer 114 may be configured by a single layer of silicon oxide (SiOx) or silicon nitride (SiNx) or a multi-layer thereof, but is not limited thereto.

The source electrode SE and the drain electrode DE electrically connected to the active layer ACT are disposed on the second interlayer insulating layer 114. The source electrode SE is connected to the second capacitor C2 and a first electrode 134 of the LED ED, and the drain electrode DE is connected to another component of the pixel circuit. Each of the source electrode SE and the drain electrode DE may be made of a conductive material, such as copper (Cu), aluminum (Al), molybdenum (Mo), nickel (Ni), titanium (Ti), chrome (Cr) or an alloy thereof, but is not limited thereto.

Then, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 interposed therebetween.

Thus, the first capacitor C1 may be connected to the gate electrode GE of the driving transistor DT to maintain a voltage of the gate electrode GE of the driving transistor DT for a predetermined period.

Then, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a as a lower capacitor electrode, the 2-2-th capacitor electrode C2b as an intermediate capacitor electrode, and the 2-3-th capacitor electrode C2c as an upper capacitor electrode.

The 2-1-th capacitor electrode C2a is disposed on the first substrate 110. The 2-1-th capacitor electrode C2a may be formed of the same material on the same layer as the light shielding layer BSM.

The 2-2-th capacitor electrode C2b is disposed on the buffer layer 111 and the gate insulating layer 112. The 2-2-th capacitor electrode C2b may be formed of the same material on the same layer as the gate electrode GE.

The 2-3-th capacitor electrode C2c is disposed on the first interlayer insulating layer 113. The 2-3-th capacitor electrode C2c may be composed of a first layer C2c1 and a second layer C2c2. The first layer C2c1 of the 2-3-th capacitor electrode C2c may be formed of the same material on the same layer as the 1-2-th capacitor electrode C1b. The first layer C2c1 may be disposed to overlap the 2-1-th capacitor electrode C2a and the 2-2-th capacitor electrode C2b with the first interlayer insulating layer 113 interposed therebetween.

The second layer C2c2 of the 2-3-th capacitor electrode C2c is disposed on the second interlayer insulating layer 114. The second layer C2c2 is a portion extending from the source electrode SE of the driving transistor DT, and may be connected to the first layer C2c1 through the contact hole of the second interlayer insulating layer 114.

Therefore, the second capacitor C2 may be electrically connected between the source electrode SE of the driving transistor DT and LEDs ED. Thus, it is possible to increase a capacitance inherent in the LED ED and enable the LED ED to emit light with a higher luminance.

A first passivation layer 115a is disposed on the driving transistor DT, the first capacitor C1, and the second capacitor C2. The first passivation layer 115a serves as an insulating layer to protect the components disposed thereunder, and may be made of an inorganic material such as silicon oxide (SiOx) or silicon nitride (SiNx), but is not limited thereto.

A first planarization layer 116a is disposed on the first passivation layer 115a. The first planarization layer 116a may serve to planarize an upper portion of the pixel circuit including the driving transistor DT. The first planarization layer 116a may be configured by a single layer or a multi-layer, and may be made of, for example, benzocyclobutene or an acryl-based organic material, but is not limited thereto. Referring to FIG. 4B and FIG. 5 together, a plurality of reflective sheets RF is disposed on the first planarization layer 116a. The reflective sheets RF are configured to reflect light emitted from the plurality of LEDs ED to above the first substrate 110. The reflective sheets RF may be disposed corresponding in shape to the plurality of sub pixels SP, respectively. Each reflective sheet RF may be disposed to cover most of a sub pixel SP. The reflective sheet RF may reflect light emitted from the LED ED and also serve as an electrode to electrically connect the LED ED to the pixel circuit. Thus, the reflective sheet RF may include various conductive layers in consideration of light reflection efficiency and resistance. For example, the reflective sheet RF may include both an opaque conductive layer made of silver (Ag), aluminum (Al), molybdenum (Mo), titanium (Ti) or an alloy thereof and a transparent conductive layer made of indium tin oxide (ITO). However, the structure of the reflective sheet RF is not limited thereto.

The reflective sheet RF includes a first reflective sheet RF1 corresponding to the first sub pixel SP1 and a second reflective sheet RF2 corresponding to the second sub pixel SP2. The reflective sheet RF also includes a third reflective sheet RF3 corresponding to the third sub pixel SP3 and a fourth reflective sheet RF4 corresponding to the fourth sub pixel SP4.

The first reflective sheet RF1 includes a 1-1-th reflective sheet RF1a overlapping most of the first sub pixel SP1 and a 1-2-th reflective sheet RF1b overlapping a first LED 130 of the first sub pixel SP1. The 1-1-th reflective sheet RF1a may reflect light emitted from the first LED 130 to above the first LED 130. Also, the 1-1-th reflective sheet RF1a may be electrically connected to the source electrode SE of the driving transistor DT and the second capacitor C2 through a first contact hole CH1 of the first planarization layer 116a and the first passivation layer 115a. Thus, the 1-1-th reflective sheet RF1a may electrically connect the driving transistor DT to the first electrode 134 of the first LED 130. The 1-2-th reflective sheet RF1b may reflect light emitted from the first LED 130 to above the first LED 130. Also, the 1-2-th reflective sheet RF1b may serve as an electrode to electrically connect a second electrode 135 of the first LED 130 to the high potential power line VL1.

The second reflective sheet RF2 includes a 2-1-th reflective sheet RF2a overlapping most of the second sub pixel SP2 and a 2-2-th reflective sheet RF2b overlapping the first LED 130 of the second sub pixel SP2. The 2-1-th reflective sheet RF2a may reflect light emitted from the first LED 130 to above the first LED 130. The 2-1-th reflective sheet RF2a may be electrically connected to the source electrode SE of the driving transistor DT and the second capacitor C2 through the first contact hole CH1. Thus, the 2-1-th reflective sheet RF2a may transmit a driving current from the driving transistor DT to the first electrode 134 of the first LED 130. Also, the 2-2-th reflective sheet RF2b may reflect light emitted from the first LED 130 to above the first LED 130. Further, the 2-2-th reflective sheet RF2b may serve as an electrode to electrically connect the second electrode 135 of the first LED 130 to the high potential power line VL1.

The third reflective sheet RF3 may be composed of the single third reflective sheet RF3 overlapping the entire third sub pixel SP3. The third reflective sheet RF3 may reflect light emitted from a second LED 140 of the third sub pixel SP3 to above the second LED 140. Also, the third reflective sheet RF3 may be electrically connected to the source electrode SE of the driving transistor DT and the second capacitor C2 through the first contact hole CH1. Thus, the third reflective sheet RF3 may transmit a driving current from the driving transistor DT to the first electrode 134 of the second LED 140.

The fourth reflective sheet RF4 may be composed of the single fourth reflective sheet RF4 overlapping the entire fourth sub pixel SP4. The fourth reflective sheet RF4 may reflect light emitted from a third LED 150 of the fourth sub pixel SP4 to above the third LED 150. Also, the fourth reflective sheet RF4 may be electrically connected to the source electrode SE of the driving transistor DT and the second capacitor C2 through the first contact hole CH1. Thus, the fourth reflective sheet RF4 may transmit a driving current from the driving transistor DT to the first electrode 134 of the third LED 150.

Meanwhile, it has been described that each of the first sub pixel SP1 and the second sub pixel SP2 includes two reflective sheets RF, and each of the third sub pixel SP3 and the fourth sub pixel SP4 includes one reflective sheet RF. However, the reflective sheet RF may be designed in various ways. For example, only one reflective sheet RF may be disposed in each of the plurality of sub pixels SP as in the third sub pixel SP3 and the fourth sub pixel SP4. Alternatively, a plurality of reflective sheets RF may be disposed as in the first sub pixel SP1 and the second sub pixel SP2. However, the present disclosure is not limited thereto.

Also, it has been described that the first LED 130 of each of the first sub pixel SP1 and the second sub pixel SP2 is electrically connected to the high potential power line VL1 through the 1-2-th reflective sheet RF1b and the 2-2-th reflective sheet RF2b. All of the first LED 130, the second LED 140, and the third LED 150 may also be connected to the high potential power line VL1 without the reflective sheet RF. However, the present disclosure is not limited thereto.

Referring to FIG. 5, a second passivation layer 115b is disposed on a plurality of reflective sheets RF. The second passivation layer 115b serves as an insulating layer to protect the components disposed thereunder. The second passivation layer 115b may be configured by a single layer of silicon oxide (SiOx) or silicon nitride (SiNx) or a multi-layer thereof, but is not limited thereto.

An adhesive layer AD is disposed on the second passivation layer 115b. The adhesive layer AD may be provided on a front surface of the first substrate 110 to fix the LED ED disposed on the adhesive layer AD. The adhesive layer AD may be made of a photocurable adhesive material which is cured by light. For example, the adhesive layer AD may be made of an acryl-based material including a photosensitizer, but is not limited thereto. The adhesive layer AD may be provided on the front surface of the first substrate 110 except a pad area in which the first pad electrode PAD1 is to be disposed.

A plurality of LEDs ED are disposed in each of the plurality of sub pixels SP on the adhesive layer AD. The LEDs ED are configured to emit light in response to a current. The LEDs ED may include the first LED 130 configured to emit red light, the second LED 140 configured to emit green light, and the third LED ED 150 configured to emit blue light. Light of various colors including white may be implemented by combination thereof. For example, each LED ED may be a light emitting diode (LED) or a micro light emitting diode (micro LED), but is not limited thereto.

The first LED 130 is disposed in each of the first sub pixel SP1 and the second sub pixel SP2. Also, a pair of second LEDs 140 is disposed in the third sub pixel SP3, and a pair of third LEDs 150 is disposed in the fourth sub pixel SP4. That is, two first LEDs 130, two second LEDs 140, and two third LEDs 150 may be disposed in one pixel PX. In this case, each first LED 130 may be individually driven as being connected to the driving transistor DT of each of the first sub pixel SP1 and the second sub pixel SP2. Meanwhile, the pair of second LEDs 140 in the third sub pixel SP3 and the pair of third LEDs 150 in the fourth sub pixel SP4 may be driven as being connected in parallel to the driving transistor DT.

The plurality of LEDs ED includes a first semiconductor layer 131, an emission layer 132, a second semiconductor layer 133, the first electrode 134, and the second electrode 135.

The first semiconductor layer 131 is disposed on the adhesive layer AD, and the second semiconductor layer 133 is disposed on the first semiconductor layer 131. Each of the first semiconductor layer 131 and the second semiconductor layer 133 may be formed by doping a specific material with n-type or p-type impurities. For example, each of the first semiconductor layer 131 and the second semiconductor layer 133 may be formed by doping a material, such as gallium nitride (GaN), indium aluminum phosphide (InAIP), or gallium arsenide (GaAs), with n-type or p-type impurities. Further, the p-type impurities may be magnesium (Mg), zinc (Zn), beryllium (Be), or the like, and the n-type impurities may be silicon (Si), germanium (Ge), tin (Sn), or the like. However, the present disclosure is not limited thereto.

The emission layer 132 is disposed between the first semiconductor layer 131 and the second semiconductor layer 133. The emission layer 132 may emit light when supplied with holes and electrons from the first semiconductor layer 131 and the second semiconductor layer 133. The emission layer 132 may be configured by a single layer or a multi-quantum well (MQW) structure and made of, for example, indium gallium nitride (InGaN) or gallium nitride (GaN), but is not limited thereto.

The first electrode 134 is disposed on the first semiconductor layer 131. The first electrode 134 serves to electrically connect the driving transistor DT to the first semiconductor layer 131. In this case, the first semiconductor layer 131 may be a semiconductor layer doped with n-type impurities, and the first electrode 134 may be a cathode. The first electrode 134 may be disposed on an upper surface of the first semiconductor layer 131 exposed from the emission layer 132 and the second semiconductor layer 133. The first electrode 134 may be made of a conductive material, for example, a transparent conductive material such as indium tin oxide (ITO) or indium zinc oxide (IZO) or an opaque conductive material such as titanium (Ti), gold (Au), silver (Ag), copper (Cu) or an alloy thereof, but is not limited thereto.

The second electrode 135 is disposed on the second semiconductor layer 133. The second electrode 135 may be disposed on an upper surface of the second semiconductor layer 133. The second electrode 135 serves to electrically connect the high potential power line VL1 to the second semiconductor layer 133. In this case, the second semiconductor layer 133 may be a semiconductor layer doped with p-type impurities, and the second electrode 135 may be an anode. The second electrode 135 may be made of a conductive material, for example, a transparent conductive material such as indium tin oxide (ITO) or indium zinc oxide (IZO) or an opaque conductive material such as titanium (Ti), gold (Au), silver (Ag), copper (Cu) or an alloy thereof, but is not limited thereto.

Then, an encapsulation film 136 is disposed to enclose the first semiconductor layer 131, the emission layer 132, the second semiconductor layer 133, the first electrode 134, and the second electrode 135. The encapsulation film 136 is made of an insulating material and may serve to protect the first semiconductor layer 131, the emission layer 132, and the second semiconductor layer 133. Further, the encapsulation film 136 includes contact holes for exposing the first electrode 134 and the second electrode 135. Thus, the encapsulation film 136 may electrically connect a first connection electrode CE1 and a second connection electrode CE2 to the first electrode 134 and the second electrode 135.

Meanwhile, a part of a side surface of the first semiconductor layer 131 may be exposed from the encapsulation film 136. The LED ED manufactured on a wafer may be separated from the wafer and then transferred onto the display panel PN. However, while the LED ED is separated from the wafer, a part of the encapsulation film 136 may be torn. For example, a part of the encapsulation film 136 adjacent to a lower edge of the first semiconductor layer 131 of the LED ED may be torn in the process of separating the LED ED from the wafer. Therefore, a part of a lower side surface of the first semiconductor layer 131 may be exposed to the outside. Even when a lower portion of the LED ED is exposed from the encapsulation film 136, it is possible to suppress a short-circuit. This is because the first connection electrode CE1 and the second connection electrode CE2 are provided after a second planarization layer 116b and a third planarization layer 116c covering the side surface of the first semiconductor layer 131 are provided.

Then, the second planarization layer 116b and the third planarization layer 116c are disposed on the adhesive layer AD and the LED ED.

The second planarization layer 116b may overlap a part of a side portion of the plurality of LEDs ED and fix and protect the plurality of LEDs ED. The second planarization layer 116b may be prepared by using a halftone mask. Thus, the second planarization layer 116b may be formed to have a step.

Specifically, a portion of the second planarization layer 116b disposed more adjacent to the LED ED may be formed to have a smaller thickness. Also, a portion of the second planarization layer 116b disposed farther from the LED ED may be formed to have a greater thickness. Thus, the portion of the second planarization layer 116b disposed adjacent to the LED ED may be disposed to enclose the LED ED and may also be in contact with a side surface of the LED ED. Therefore, a portion of the encapsulation film 136 protecting the side surface of the first semiconductor layer 131 of the LED ED may be torn while the LED ED is separated from the wafer and then transferred onto the display panel PN. The torn portion may be covered by the second planarization layer 116b. Accordingly, it is possible to thereafter suppress a contact failure and a short-circuit between the connection electrodes CE1 and CE2 and the first semiconductor layer 131.

The third planarization layer 116c may be formed to cover upper portions of the second planarization layer 116b and LEDs ED. Also, the third planarization layer 116c may include contact holes for exposing the first electrode 134 and the second electrode 135 of the LED ED. The first electrode 134 and the second electrode 135 of the LED ED are exposed from the third planarization layer 116c. Also, the third planarization layer 116c is partially disposed between the first electrode 134 and the second electrode 135. Therefore, it is possible to suppress a short-circuit. The second planarization layer 116b and the third planarization layer 116c may be configured by a single layer or a multi-layer, and may be made of, for example, photo resist or an acryl-based organic material, but is not limited thereto.

Meanwhile, the third planarization layer 116c may cover only the LED ED and a region adjacent to the LED ED. The third planarization layer 116c may be disposed in an island shape in the sub pixel SP enclosed by a bank BB. Thus, the bank BB may be disposed on a part of an upper surface of the second planarization layer 116b, and the third planarization layer 116c may be disposed on another part of the upper surface of the second planarization layer 116b.

The first connection electrode CE1 and the second connection electrode CE2 are disposed on the third planarization layer 116c. The first connection electrode CE1 serves to electrically connect the second electrode 135 of the LED ED to the high potential power line VL1. The first connection electrode CE1 may be electrically connected to the second electrode 135 of the LED ED through the contact hole formed in the third planarization layer 116c.

The second connection electrode CE2 serves to electrically connect the first electrode 134 of the LED ED to the driving transistor DT. The second connection electrode CE2 may be connected to the 1-1-th reflective sheet RF1a, the 1-2-th reflective sheet RF1b, the third reflective sheet RF3, and the fourth reflective sheet RF4 of the plurality of sub pixels SP through the contact hole formed in the third planarization layer 116c, the second planarization layer 116b, the adhesive layer AD, and the second passivation layer 115b. In this case, the 1-1-th reflective sheet RF1a, the 1-2-th reflective sheet RF1b, the third reflective sheet RF3, and the fourth reflective sheet RF4 are also connected to the source electrode SE of the driving transistor DT. Thus, the source electrode SE of the driving transistor DT may be electrically connected to the first electrode 134 of the LED ED.

Meanwhile, it is illustrated in the drawings that the first electrode 134, the second connection electrode CE2, and the reflective sheet RF are electrically connected to the source electrode SE of the driving transistor DT. However, the first electrode 134, the second connection electrode CE2, and the reflective sheet RF may be connected to the drain electrode DE of the driving transistor DT, but are not limited thereto.

The bank BB is disposed on the first connection electrode CE1 and the second planarization layer 116b exposed from the second connection electrode CE2 and the third planarization layer 116c. The bank BB may be disposed to be spaced apart from the LED ED by a predetermined interval, and at least a part of the bank BB may overlap the reflective sheet RF. For example, the bank BB may cover a part of the second connection electrode CE2 formed inside the contact hole of the third planarization layer 116c and the second planarization layer 116b. Also, the bank BB may be disposed on the second planarization layer 116b so as to be spaced apart from, for example, the LED ED by a predetermined interval. In this case, the bank BB and the third planarization layer 116c may be spaced apart from each other on the portion of the second planarization layer 116b having a smaller thickness. That is, an end point of the bank BB may be disposed to be spaced apart from an end point of the third planarization layer 116c on the portion of the second planarization layer 116b having a smaller thickness and formed by using a halftone mask.

The bank BB may be made of an opaque material to suppress color mixture between the plurality of sub pixels SP. For example, the bank BB may be made of black resin, but is not limited thereto.

Meanwhile, a portion of the bank BB formed in the contact hole of the third planarization layer 116c and the second planarization layer 116b and covering a part of the second connection electrode CE2 may be different in thickness from another portion of the bank BB disposed on the second planarization layer 116b. Specifically, the contact hole is formed from the second passivation layer 115b to the third planarization layer 116c. Thus, the portion of the bank BB formed in the contact hole of the third planarization layer 116c and the second planarization layer 116b and covering a part of the second connection electrode CE2 may be disposed to below the LED ED, i.e., to a position lower than the LED ED. Therefore, the portion of the bank BB formed in the contact hole of the third planarization layer 116c and the second planarization layer 116b and covering a part of the second connection electrode CE2 may have a greater thickness than the portion of the bank BB disposed on the second planarization layer 116b.

A first protection layer 117 is disposed on the first connection electrode CE1, the second connection electrode CE2, and the bank BB. The first protection layer 117 serves to protect the components disposed thereunder. The first protection layer 117 may be configured by a single layer or a multi-layer, and may be made of, for example, benzocyclobutene, transparent epoxy, photo resist, or an acryl-based organic material, but is not limited thereto.

A second substrate 120 is disposed under the first substrate 110. The second substrate 120 serves to support the components disposed under the display device 100, and may be an insulating substrate. For example, the second substrate 120 may be made of glass or resin. The second substrate 120 may also contain a polymer or plastic. The second substrate 120 may be made of the same material as the first substrate 110. In some exemplary embodiments, the second substrate 120 may be made of a plastic material having flexibility.

A bonding layer BDL is disposed between the first substrate 110 and the second substrate 120. The bonding layer BDL may be made of a material capable of being cured through various curing methods to bond the first substrate 110 and the second substrate 120 to each other. The bonding layer BDL may be disposed in a partial area or the entire area between the first substrate 110 and the second substrate 120.

Further, a second protection layer 121 is disposed under the second substrate 120. The second protection layer 121 may serve to protect various lines and driving components provided on the second substrate 120. The second protection layer 121 may be made of an organic insulating material, for example, benzocyclobutene or an acryl-based organic insulating material, but is not limited thereto.

An encapsulation layer 160 is disposed on the first protection layer 117 and under the second protection layer 121. The encapsulation layer 160 serves to minimize the permeation of moisture from the outside of the display device 100 and encapsulate the components enclosed by the encapsulation layer 160. The encapsulation layer 160 may be disposed to enclose the first substrate 110 and front, side and rear surfaces of the second substrate 120.

The encapsulation layer 160 may be made of a material having low water permeability and high insulation. For example, the encapsulation layer 160 may be made of a material including parylene, but is not limited thereto.

Referring to FIG. 5, an optical film MF is disposed on the entire surface of the first substrate 110 so as to cover an upper portion of the encapsulation layer 160. The optical film MF may be a function film to protect the display device 100 and realize images with higher quality. For example, the optical film MF may include an anti-scattering film, an anti-glare film, an anti-reflecting film, a low-reflecting film, an OLED transmittance controllable film, or a polarizing plate, but is not limited thereto.

An adhesive member 118 is disposed between the first protection layer 117 and the optical film MF on the first substrate 110. The adhesive member 118 may be provided on the entire surface of the first substrate 110 to bond the first protection layer 117 to the optical film MF. The adhesive member 118 may be made of a photocurable adhesive material which is cured by light. For example, the adhesive member 118 may be made of an acryl-based material including a photosensitizer, but is not limited thereto.

Meanwhile, in the present disclosure, the adhesive member 118 is defined as a component separate from the optical film MF. However, the present disclosure is not limited thereto. The optical film MF and the adhesive member 118 may also be defined as a single component.

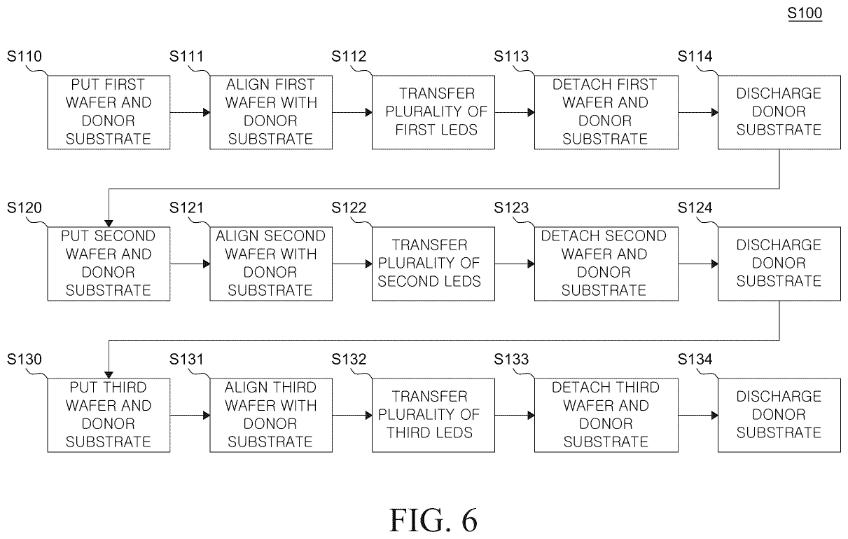

Hereinafter, a method of manufacturing the display device 100 according to an exemplary embodiment of the present disclosure will be described with reference to FIG. 6 through FIG. 8.

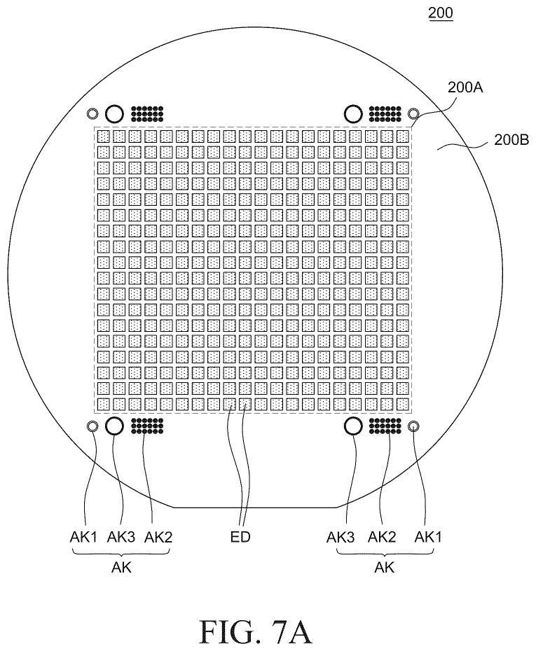

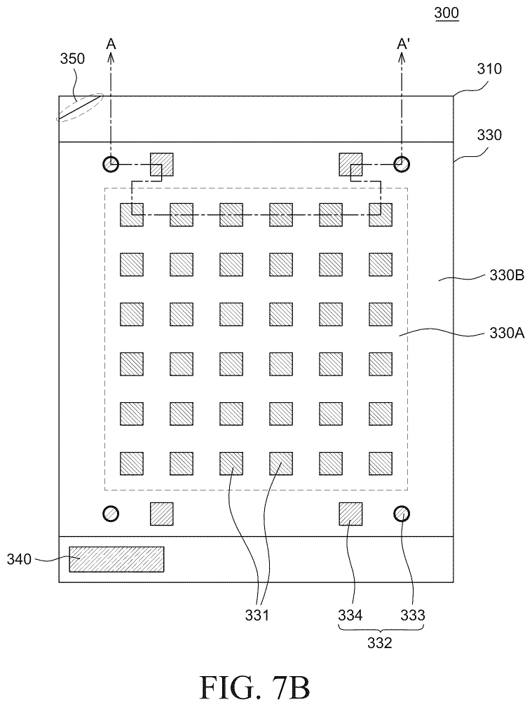

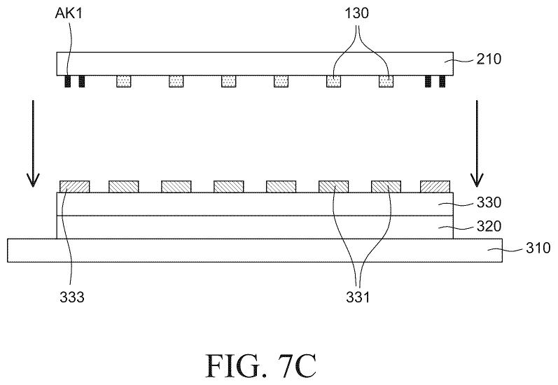

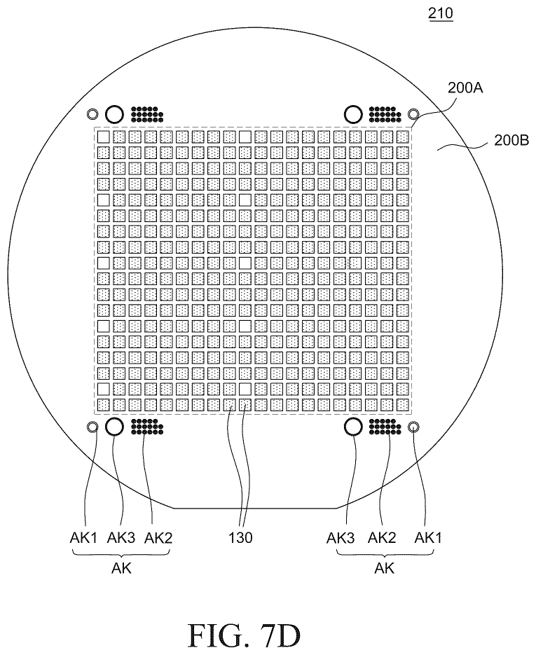

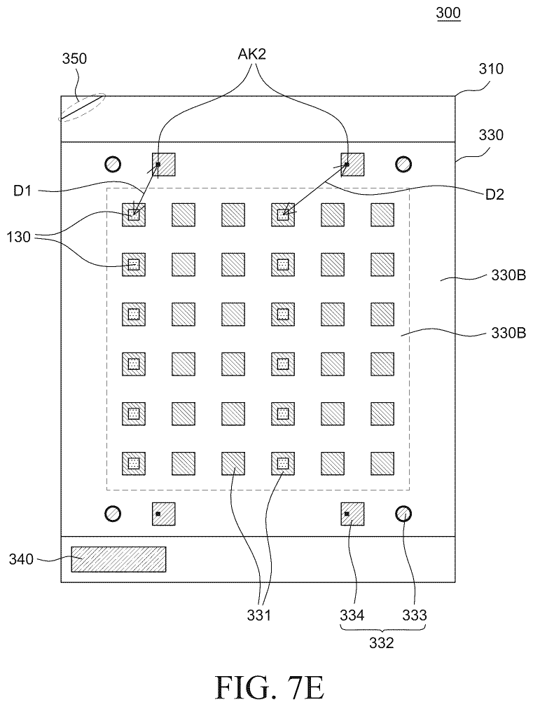

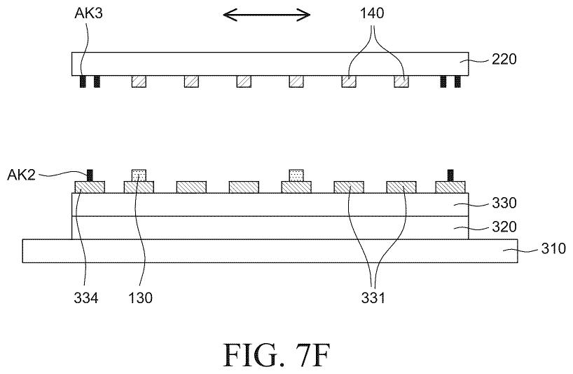

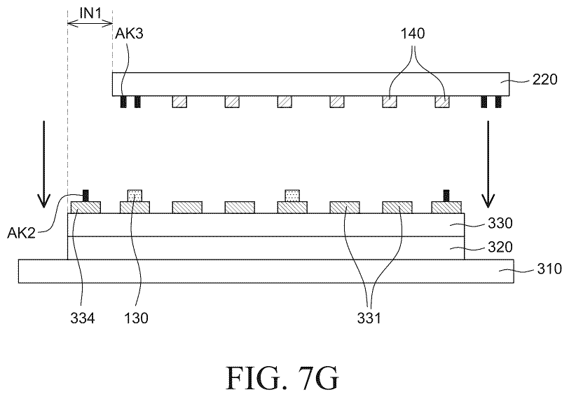

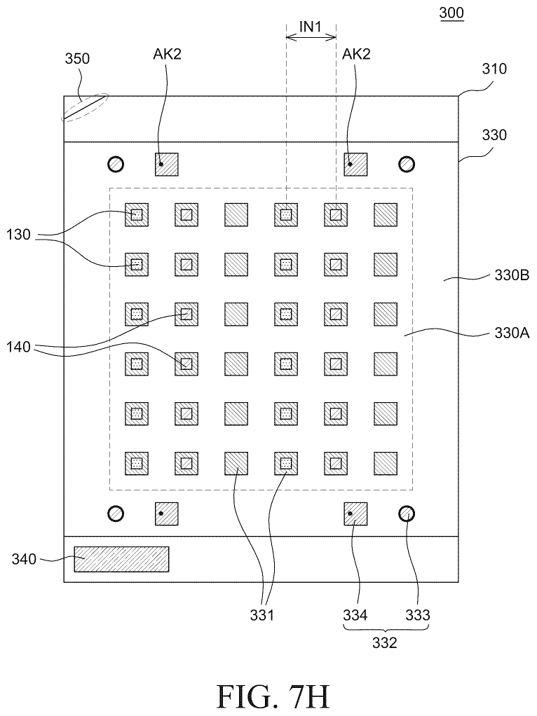

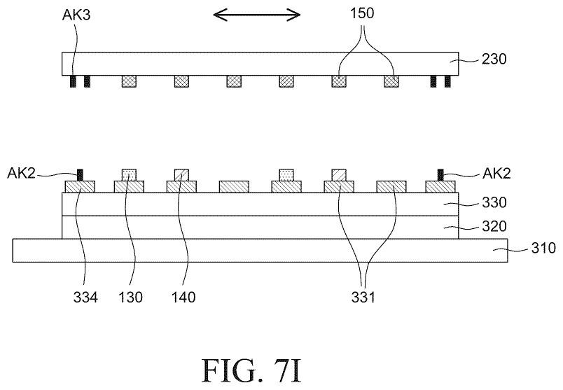

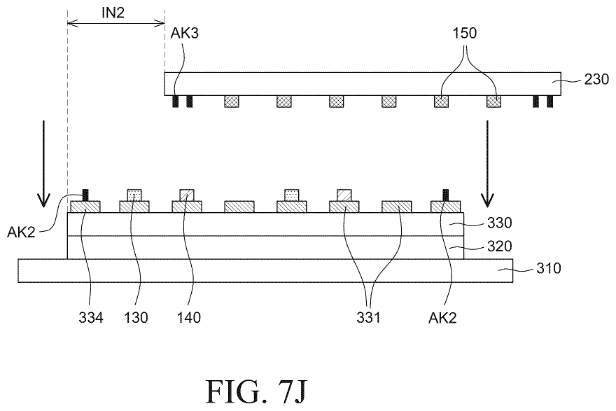

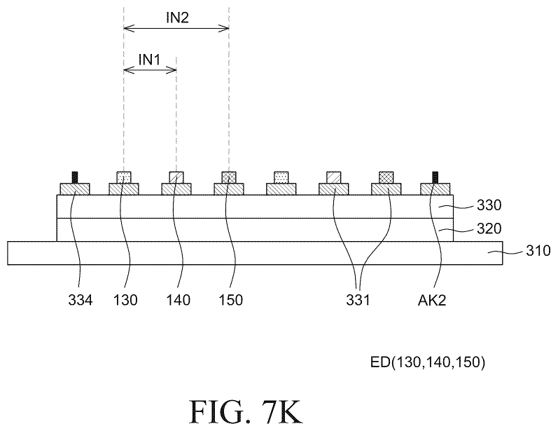

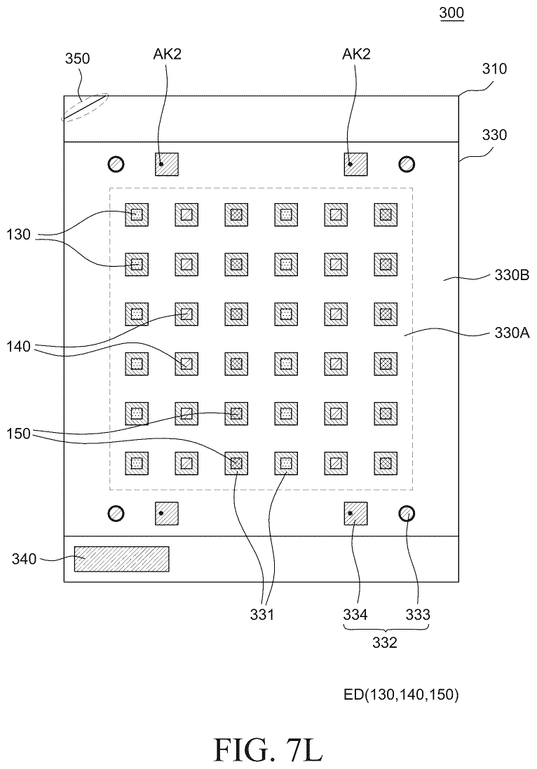

FIG. 6 is a process flowchart for explaining a method of manufacturing a display device according to an exemplary embodiment of the present disclosure. FIG. 7A through FIG. 7L are schematic process diagrams for explaining the method of manufacturing a display device according to an exemplary embodiment of the present disclosure. Specifically, FIG. 6 is a flowchart for explaining a primary transfer process of transferring, onto a donor substrate 300, a plurality of LEDs ED on a wafer 200. FIG. 7A through FIG. 7L are schematic process diagrams for explaining the primary transfer process. FIG. 7C, FIG. 7F, FIG. 7G, FIG. 7I, FIG. 7J, and FIG. 7K are cross-sectional views taken along the line A-A′ of FIG. 7B. Hereinafter, the description will be made under the assumption that the first LED 130 is a red LED, the second LED 140 is a green LED, the third LED 150 is a blue LED, the first sub pixel SP1 and the second sub pixel SP2 are red sub pixels, the third sub pixel SP3 is a green sub pixel, and the fourth sub pixel SP4 is a blue sub pixel. However, the present disclosure is not limited thereto.

When the primary transfer process is performed, the plurality of LEDs ED on the wafer 200 may be transferred onto the donor substrate 300. When a secondary transfer process is performed, the plurality of LEDs ED on the donor substrate 300 may be transferred onto the display panel PN. Thus, a manufacturing process of the display device 100 may be completed by transferring the plurality of LEDs ED from the wafer 200 onto the donor substrate 300 and from the donor substrate 300 onto the display panel PN.

Hereinafter, a primary transfer process S100 will be described first with reference to FIG. 6, FIG. 7A to FIG. 7I.

Referring to FIG. 6 and FIG. 7A, the wafer 200 is a substrate on which the plurality of LEDs ED are disposed. The plurality of LEDs ED may be prepared by forming a material, such as gallium nitride (GaN) or indium gallium nitride (InGaN), of the plurality of LEDs ED on the wafer 200 to grow a crystal layer, cutting the crystal layer into individual chips, and forming electrodes. The wafer 200 may be made of sapphire, silicon carbide (SiC), gallium nitride (GaN), zinc oxide (ZnO), or the like, but is not limited thereto.

In this case, the plurality of LEDs ED which emit light of the same color may be formed on the wafer 200, or the plurality of LEDs ED which emit light of different colors may be formed thereon. Hereinafter, the description will be made under the assumption that the plurality of LEDs ED which emit light of the same color is formed on the wafer 200.

The wafer 200 includes an active area 200A and a peripheral area 200B. The active area 200A refers to an area in which the plurality of LEDs ED are disposed, and the peripheral area 200B disposed outside the active area 200A refers to an area in which a plurality of alignment keys AK are disposed.

The plurality of alignment keys AK include a first alignment key AK1, a second alignment key AK2, and a third alignment key AK3. The first alignment key AK1, the second alignment key AK2, and the third alignment key AK3 may be disposed around an edge of the wafer 200 in the peripheral area 200B. However, the first alignment key AK1, the second alignment key AK2, and the third alignment key AK3 may be disposed at other positions than the edge of the wafer 200 depending on the design. Also, the numbers of first alignment keys AK1, second alignment keys AK2 and third alignment keys AK3 may be designed in various ways.

The first alignment key AK1 is used to align a first wafer 210 and the donor substrate 300. Herein, the first wafer 210 refers to a wafer on which LEDs to be transferred first onto the donor substrate 300 are formed. The first alignment key AK1 is a mark for adjusting alignment and parallelism with the donor substrate 300 when a plurality of first LEDs 130 of the first wafer 210 are transferred onto the donor substrate 300. For example, alignment and parallelism between the wafer 200 and the donor substrate 300 may be adjusted by aligning the first alignment key AK1 of the wafer 200 and an alignment protrusion 332 of the donor substrate 300.

The second alignment key AK2 is used to align the donor substrate 300 and the display panel PN. The second alignment key AK2 may be transferred onto the donor substrate 300 together with the plurality of LEDs ED when the plurality of LEDs ED of the first wafer 210 is transferred onto the donor substrate 300. Then, alignment and parallelism between the donor substrate 300 and the display panel PN may be adjusted by using the second alignment key AK2 on the donor substrate 300.

Further, the second alignment key AK2 and the third alignment key AK3 are marks for adjusting alignment and parallelism with the donor substrate 300 when a plurality of second LEDs 140 of a second wafer 220 and a plurality of third LEDs 150 of a third wafer 230 are transferred onto the donor substrate 300. Herein, the second wafer 220 refers to the wafer 200 on which LEDs to be transferred second onto the donor substrate 300 are formed. Also, the third wafer 230 refers to the wafer 200 on which LEDs to be transferred third onto the donor substrate 300 are formed. For example, alignment and parallelism may be adjusted by using the third alignment key AK3 of the second wafer 220 and the second alignment key AK2 transferred onto the donor substrate 300. Also, alignment and parallelism may be adjusted by using the third alignment key AK3 of the third wafer 230 and the second alignment key AK2 transferred onto the donor substrate 300. A transfer process using the second wafer 220 and the third wafer 230 will be described in detail with reference to FIG. 7E through FIG. 7L.

The first alignment key AK1, the second alignment key AK2, and the third alignment key AK3 may be formed together when the plurality of LEDs ED are formed. Alternatively, the first alignment key AK1, the second alignment key AK2, and the third alignment key AK3 may be formed by a separate process from a process of forming the plurality of LEDs ED. If the first alignment key AK1, the second alignment key AK2, and the third alignment key AK3 formed together with the plurality of LEDs ED, the first alignment key AK1, the second alignment key AK2, and the third alignment key AK3 may be made of the same materials as at least some of the materials forming the plurality of LEDs ED. However, the materials and forming processes of the first alignment key AK1, the second alignment key AK2, and the third alignment key AK3 may be variously configured depending on the design, but are not limited thereto.

The shapes and sizes of the plurality of alignment keys AK may be variously configured. For example, in order to identify the first alignment key AK1, the second alignment key AK2, and the third alignment key AK3 disposed in the peripheral area 200B, the first alignment key AK1, the second alignment key AK2, and the third alignment key AK3 may have different shapes or sizes from one another. For example, the first alignment key AK1 and the third alignment key AK3 may have a greater size than the second alignment key AK2, but are not limited thereto.

Meanwhile, a plurality of second alignment keys AK2 may correspond in shape to a plurality of third alignment keys AK3, respectively. Herein, the correspondence in shape between the second alignment key AK2 and the third alignment key AK3 may imply that the shapes of the second alignment key AK2 and the third alignment key AK3 are determined to adjust alignment using the second alignment key AK2 and the third alignment key AK3 in the alignment process.

For example, the plurality of second alignment keys AK2 may have a circular shape, and the plurality of third alignment keys AK3 may have a ring shape with a hole corresponding to the shape of the plurality of second alignment keys AK2, respectively. Thus, in the alignment process, a center of the second alignment key AK2 having a circular shape may be aligned with a center of the hole of the third alignment key AK3 having a ring shape.

Also, for example, the second alignment key AK2 may have a “+” shape, and the third alignment key AK3 may have a “x” shape. Thus, in the alignment process, a central point of the “+” shape of the second alignment key AK2 may be aligned to overlap a central point of the “x” shape of the third alignment key AK3.

However, the second alignment key AK2 and the third alignment key AK3 are not limited to the above description, and may have various shapes suitable for the alignment process. Hereinafter, the second alignment key AK2 and the third alignment key AK3 will be described as having a circular shape and a ring shape, respectively, for convenience in explanation.

Meanwhile, a plurality of first alignment keys AK1, the plurality of second alignment keys AK2, and the plurality of third alignment keys AK3 may be distributed in four regions corresponding to edges of the active area of the wafer 200. For example, the plurality of first alignment keys AK1, the plurality of second alignment keys AK2, and the plurality of third alignment keys AK3 may be distributed in regions adjacent to an upper left end, an upper right end, a lower left end, and a lower right end of the wafer 200. In this case, one of the plurality of first alignment keys AK1 and one of the plurality of third alignment keys AK3 may be disposed in each of the four regions, and a plurality of second alignment keys AK2 may be disposed in each of the four regions. FIG. 7A illustrates that 18 second alignment keys AK2 are disposed in each of the four regions, but the present disclosure is not limited thereto.

In each of the four regions, an interval (e.g., a distance) between the third alignment key AK3 and one of the plurality of second alignment keys AK2 located at a corresponding position may be constant. That is, in each of the four regions, the interval between the third alignment key AK3 and one of the plurality of second alignment keys AK2 located at the same position is the same across each region. For example, referring to FIG. 7A, in each of the four regions, an interval between the third alignment key AK3 and an uppermost and rightmost second alignment key AK2 of the plurality of second alignment keys AK2 in the same direction may be constant (e.g., the same).

Thus, the alignment keys AK in a left region of the four regions may be disposed differently from the alignment keys AK in a right region. Referring to FIG. 7A, in the upper right end and the lower right end, the third alignment key AK3, the plurality of second alignment keys AK2, and the first alignment key AK1 may be disposed sequentially from the left side to the right side. However, in the upper left end and the lower left end, the first alignment key AK1, the third alignment key AK3, and the plurality of second alignment keys AK2 may be disposed sequentially from the left side to the right side.

Referring to FIG. 7B, the donor substrate 300 includes a base layer 310, an adhesive layer 320, a resin layer 330, a plurality of protrusions 331, and a plurality of alignment protrusions 332.

The base layer 310 is configured to support various components included in the donor substrate 300, and may be made of a more rigid material than at least the resin layer 330 to minimize bending of the resin layer 330. The base layer 310 may be disposed under the resin layer 330 to support the resin layer 330, the plurality of protrusions 331, and the plurality of alignment protrusions 332. For example, the base layer 310 may contain a polymer or plastic and may be made of poly carbonate (PC) or polyethylene terephthalate (PET), but is not limited thereto.

Meanwhile, an identification pattern 340 and an orientation pattern 350 may be disposed on a portion of the base layer 310 protruding toward the outside of the resin layer 330.

The identification pattern 340 is a pattern formed on the base layer 310 to identify the donor substrate 300. A plurality of donor substrates 300 may be managed using unique identification patterns 340 given to the respective donor substrates 300. The identification pattern 340 may be disposed on an upper surface or a rear surface of the base layer 310 and may be formed by a printing method or a laser engraving method. For example, the identification pattern 340 may be an identifier (ID) composed of numbers or characters or a barcode, but is not limited thereto. Meanwhile, FIG. 7B illustrates that a single identification pattern 340 is formed on a lower left end of the donor substrate 300. However, the number and disposition of identification patterns 340 are not limited thereto.

The orientation pattern 350 is a pattern formed on the base layer 310 to distinguish the orientation of the donor substrate 300. For example, when the donor substrate 300 is put into the process equipment, if the donor substrate 300 is put in the opposite direction, the LEDs ED may be transferred to a different position from the designed position or a defect may occur. Accordingly, the orientation pattern 350 may be disposed on any one portion of the base layer 310 to distinguish the orientation of the donor substrate 300. The orientation pattern 350 may be formed by a printing method or a laser engraving method or may be formed by chamfering an edge of the base layer 310, but is not limited thereto. In the example, shown in FIG. 7B, the orientation pattern 350 (e.g., a chamfer) is at the top left corner of the base layer 310.

The resin layer 330 is disposed on the base layer 310. In the transfer process, the resin layer 330 may support the plurality of protrusions 331 to which the plurality of LEDs ED are attached. The resin layer 330 may be made of a polymer resin having viscoelasticity. For example, the resin layer 330 may be made of poly di methyl siloxane (PDMS), poly urethane acrylate (PUA), polyethylene glycol (PEG), poly methyl meth acrylate (PMMA), poly styrene (PS), epoxy resin, urethane resin, acryl resin, etc., but is not limited thereto.

The resin layer 330 includes a transfer area 330A and a non-transfer area 330B.

The transfer area 330A is an area in which the plurality of protrusions 331 are disposed. The transfer area 330A is an area in which the plurality of protrusions 331 to which the plurality of LEDs ED are attached are disposed. The transfer area 330A may be disposed to overlap at least a part of the wafer 200 or the display panel PN in the transfer process.

The non-transfer area 330B is an area in which the plurality of alignment protrusions 332 are disposed. The plurality of LEDs ED of the wafer 200 may not be transferred onto the non-transfer area 330B, but the second alignment key AK2 of the wafer 200 may be transferred onto the non-transfer area 330B.

The plurality of protrusions 331 may be protrusions 331 on which the plurality of LEDs ED are disposed, and may extend from one surface of the resin layer 330. The plurality of protrusions 331 may be integrally formed with the resin layer 330, and may be made of a polymer material having viscoelasticity like the resin layer 330. For example, the plurality of protrusions 331 may be made of poly di methyl siloxane (PDMS), poly urethane acrylate (PUA), polyethylene glycol (PEG), poly methyl meth acrylate (PMMA), poly styrene (PS), epoxy resin, urethane resin, acryl resin, etc., but is not limited thereto.

The plurality of LEDs ED may be temporarily attached to upper surfaces of the plurality of protrusions 331. The plurality of LEDs ED formed on the wafer 200 may be transferred onto the upper surfaces of the plurality of first protrusions 331. Also, the plurality of LEDs ED may temporarily continue to be attached to the upper surfaces of the plurality of protrusions 331 before being transferred onto the display panel PN.

In this case, the plurality of protrusions 331 may be disposed at the same interval (e.g., distance) as the interval between the plurality of sub pixels SP. For example, when the plurality of LEDs ED are transferred onto the display panel PN, the plurality of LEDs ED are transferred corresponding to the plurality of sub pixels SP, respectively. If the plurality of LEDs ED transferred onto the donor substrate 300 are transferred at same a time, the plurality of LEDs ED on the donor substrate 300 needs to be disposed corresponding to the plurality of sub pixels SP, respectively. In this case, the plurality of LEDs ED transferred onto the display panel PN at same a time may be transferred corresponding to the plurality of sub pixels SP, respectively. However, the disposition and interval of the plurality of protrusions 331 may vary depending on the design, but are not limited thereto.

The plurality of protrusions 331 may have a greater size (e.g., area) than the plurality of LEDs ED. The upper surfaces of the plurality of protrusions 331 are formed to have a greater size than the plurality of LEDs ED. Thus, even if an alignment error between the donor substrate 300 and the wafer 200 occurs, the plurality of LEDs ED may be mounted on the plurality of protrusions 331. Accordingly, in consideration of the alignment error between the wafer 200 and the donor substrate 300, the upper surfaces of the plurality of protrusions 331 may be formed to have a greater size than the plurality of LEDs ED.

The plurality of alignment protrusions 332 are disposed in the non-transfer area 330B. The plurality of alignment protrusions 332 include a plurality of first alignment protrusions 333 and a plurality of second alignment protrusions 334.

The plurality of first alignment protrusions 333 are used to align the first wafer 210 and the donor substrate 300. The plurality of first alignment protrusions 333 may be disposed corresponding to the first alignment key AK1 of the first wafer 210. For example, alignment and parallelism between the first wafer 210 and the donor substrate 300 may be adjusted by aligning the first alignment key AK1 of the first wafer 210 and the first alignment protrusion 333 of the donor substrate 300. In this case, the first alignment protrusion 333 may be different in shape or size from the first alignment key AK1 to facilitate identification. For example, the first alignment protrusion 333 may have a circular shape, and the first alignment key AK1 may have a ring shape with a hole in the middle. However, the present disclosure is not limited thereto.

The second alignment protrusion 334 may be disposed corresponding to the second alignment key AK2 of the first wafer 210. For example, after aligning the first alignment key AK1 of the first wafer 210 and the first alignment protrusion 333 of the donor substrate 300 to align the first wafer 210 and the donor substrate 300, the plurality of LEDs ED of the first wafer 210 may be transferred onto the plurality of protrusions 331 of the donor substrate 300. Also, the second alignment key AK2 of the first wafer 210 may be transferred onto the second alignment protrusion 334 of the donor substrate 300. In this case, the second alignment key AK2 of the first wafer 210 transferred onto the donor substrate 300 may be used later to align the second wafer 220 with the donor substrate 300, the third wafer 230 with the donor substrate 300, and the display panel PN with the donor substrate 300.

Meanwhile, the plurality of protrusions 331 may not be disposed in the donor substrate 300, and the plurality of LEDs ED may be directly transferred onto the resin layer 330. That is, the donor substrate 300 may not include the separate protrusions 331. The structure of the donor substrate 300 may vary depending on the shape, disposition, and transfer method of the plurality of LEDs ED, but is not limited thereto. Hereinafter, the description will be made under the assumption that the donor substrate 300 includes the plurality of protrusions 331 and the plurality of LEDs ED are transferred to the plurality of protrusions 331, respectively, for convenience in explanation.

The adhesive layer 320 is disposed between the resin layer 330 and the base layer 310. The adhesive layer 320 bonds the resin layer 330 to the display panel PN. The adhesive layer 320 may be made of a material having adhesiveness, for example, optical clear adhesive (OCA), pressure sensitive adhesive (PSA), or the like, but is not limited thereto.

However, the adhesive layer 320 may be omitted depending on the design. For example, the resin layer 330 may be formed by coating a material forming the resin layer 330 directly on the base layer 310 and then curing the material. In this case, since the resin layer 330 may be attached to the base layer 310 even if the adhesive layer 320 is not disposed, the adhesive layer 320 may be omitted depending on the design, but is not limited thereto.

Referring FIG. 7C through FIG. 7E together, the first wafer 210 on which the plurality of first LEDs 130 are formed and the donor substrate 300 are put (e.g., placed) into the process equipment (S110). The first wafer 210 is placed over the donor substrate 300 in the process equipment. Then, the first wafer 210 and the donor substrate 300 in the process equipment are aligned (S111). In a state where the first wafer 210 and the donor substrate 300 are disposed such that the plurality of first LEDs 130 on the first wafer 210 and the plurality of protrusions 331 of the donor substrate 300 face each other, the first wafer 210 may be aligned with the donor substrate 300. Specifically, the first wafer 210 and the donor substrate 300 may be aligned by aligning the center of the first alignment key AK1 of the first wafer 210 with the center of the first alignment protrusion 333 of the donor substrate 300.

After the alignment between the first wafer 210 and the donor substrate 300 is completed, the plurality of first LEDs 130 of the first wafer 210 are transferred onto the donor substrate 300 (S112). In a state where the first wafer 210 and the donor substrate 300 are disposed to face each other, a laser may be selectively irradiated only to the first LED 130 to be transferred onto the donor substrate 300 among the plurality of first LEDs 130. The first LED 130 irradiated with the laser may be detached from the first wafer 210 and then attached to the plurality of protrusions 331 of the donor substrate 30.

In this case, at least some of the plurality of second alignment keys AK2 of the wafer 200 may also be transferred onto the donor substrate 300. In a state where the first wafer 210 and the donor substrate 300 are disposed to face each other, a laser may be selectively irradiated only to some of the plurality of second alignment keys AK2 to be transferred onto the donor substrate 300. The second alignment keys AK2 irradiated with the laser may be detached from the first wafer 210 and then attached to the second alignment protrusions 334 of the donor substrate 300.

Referring to FIG. 7D, after the transfer of the plurality of first LEDs 130 and the second alignment keys AK2 is completed, some of the first LEDs 130 and some of the second alignment keys AK2, which are not transferred onto the donor substrate 300, may remain on the first wafer 210. Further, the first LEDs 130 and second alignment keys AK2 remaining on the first wafer 210 may be transferred onto another donor substrate 300.

Referring to FIG. 7E, the plurality of first LEDs 130 may be transferred onto the protrusions 331 at positions corresponding to the first sub pixel SP1 and the second sub pixel SP2 among the plurality of protrusions 331 of the donor substrate 300. The plurality of first LEDs 130 may be LEDs ED disposed in the first sub pixel SP1 and the second sub pixel SP2. Further, the plurality of protrusions 331 of the donor substrate 300 are disposed corresponding to the sub pixels SP. Accordingly, the plurality of first LEDs 130 are transferred onto some protrusions 331 to be aligned corresponding to the first sub pixel SP1 and the second sub pixel SP2 in a secondary transfer process to be described later among the plurality of protrusions 331 of the donor substrate 300. Thus, the plurality of first LEDs 130 may be transferred onto the first sub pixel SP1 and the second sub pixel SP2 of the display panel PN at a same time.

Meanwhile, an interval between a specific first LED 130 among the plurality of first LEDs 130 and the second alignment key AK2 transferred to the donor substrate 300 is always constant. Specifically, an interval between the first LEDs 130 disposed at the shortest distance from a specific second alignment key AK2 on the first wafer 210 and an interval between the first LEDs 130 disposed at the shortest distance from a specific second alignment key AK2 on the donor substrate 300 may be constant. For example, the second alignment key AK2 disposed at an upper left end among the four second alignment keys AK2 transferred onto the donor substrate 300 and the first LED 130 disposed at the upper left end to be closest thereto may have an interval (e.g., a distance) of D1 on the first wafer 210 and may also have the interval of D1 on the donor substrate 300. Further, the second alignment key AK2 disposed at an upper right end among the four second alignment keys AK2 transferred onto the donor substrate 300 and the first LED 130 disposed at the upper right end to be closest thereto may have an interval (e.g., a distance) of D2 on the first wafer 210 and may also have the interval of D2 on the donor substrate 300. That is, when the plurality of first LEDs 130 and the plurality of second alignment keys AK2 are transferred, the plurality of second alignment keys AK2 may be transferred at a predetermined interval from the respective first LEDs 130 disposed at the shortest distance.

Therefore, if the plurality of second alignment keys AK2 are disposed to deviate from their correct positions on the plurality of second alignment protrusions 334, the plurality of first LEDs 130 at a predetermined interval from the plurality of second alignment keys AK2, respectively, may also be disposed to deviate from their correct positions on the plurality of protrusions 331. Accordingly, the positions of the plurality of first LEDs 130 may be easily identified through the second alignment keys AK2.

After the plurality of first LEDs 130 of the first wafer 210 are transferred onto the donor substrate 300, the first wafer 210 and the donor substrate 300 are detached (S113). Then, the donor substrate 300 onto which the first LEDs 130 are transferred is discharged from the process equipment (S114).

Then, the donor substrate 300 on which the first LEDs 130 are disposed and the second wafer 220 on which the plurality of second LEDs 140 are formed are put into the process equipment (S120). Thereafter, the second wafer 220 and the donor substrate 300 are aligned (S121), and the plurality of second LEDs 140 are transferred onto the donor substrate 300 (S122).

Referring to FIG. 7F, in a state where the second wafer 220 and the donor substrate 300 are disposed over each other such that the plurality of second LEDs 140 on the second wafer 220 and the plurality of protrusions 331 of the donor substrate 300 face each other, the second wafer 220 may be aligned with the donor substrate 300.

In this case, the first wafer 210 is aligned with the donor substrate 300 based on the first alignment key AK1 and the first alignment protrusion 333. However, the second wafer 220 and the donor substrate 300 may be aligned based on at least some of the plurality of second alignment keys AK2 transferred onto the donor substrate 300 from the first wafer 210 and the third alignment keys AK3 of the second wafer 220.

Specifically, when the donor substrate 300 on which the plurality of first LEDs 130 and the plurality of second alignment keys AK2 are disposed is aligned with the second wafer 220, they may be aligned based on one or more second alignment keys AK2 among the plurality of second alignment keys AK2 disposed on the donor substrate 300 and any one component among the components of the second wafer 220. For example, the second wafer 220 and the donor substrate 300 may be aligned based on some of the plurality of second alignment keys AK2 of the first wafer 210 that are transferred onto the donor substrate 300 from the first wafer 210 and the third alignment keys AK3 of the second wafer 220. Specifically, the plurality of second alignment keys AK2 of the first wafer 210 that are disposed on the donor substrate 300 may be aligned with the plurality of third alignment keys AK3 of the second wafer 220 corresponding in shape to the plurality of second alignment keys AK2. For example, if the second alignment key AK2 has a circular shape and the third alignment key AK3 has a ring shape with a hole corresponding to the second alignment key AK2, an alignment process may be performed by aligning the second alignment key AK2 with the hole of the third alignment key AK3.

As described above, an interval between the second alignment key AK2 and the first LED 130 disposed on the donor substrate 300 is always constant. Thus, the position of the first LED 130 may be identified through the second alignment key AK2. Accordingly, when the second wafer 220 is aligned with the donor substrate 300 based on the second alignment key AK2 disposed on the donor substrate 300, a relative position between the plurality of first LEDs 130 on the donor substrate 300 and the plurality of second LEDs 140 of the second wafer 220 may be aligned. For example, the plurality of first LEDs 130 and the plurality of second LEDs 140 on the donor substrate 300 may be transferred onto the display panel PN at a same time at an interval between the plurality of sub pixels SP on the donor substrate 300. For example, the second wafer 220 may be shifted by the interval between the plurality of sub pixels SP, and then, the plurality of second LEDs 140 may be transferred onto the donor substrate 300.

In this case, only the plurality of second LEDs 140 may be transferred onto the donor substrate 300 from the second wafer 220, but the plurality of second alignment keys AK2 and the third alignment key AK3 may not be transferred. Since different masks or lasers are used for the plurality of second LEDs 140, the plurality of second alignment keys AK2, and the third alignment key AK3 in the transfer process, they may not be transferred simultaneously onto the donor substrate 300, but may be transferred sequentially. If the plurality of first LEDs 130, the plurality of second LEDs 140, and the plurality of third LEDs 150 are transferred onto respective donor substrates 300, the plurality of second alignment keys AK2 and the third alignment key AK3 may be transferred to each of the donor substrates 300 to align the display panel PN and the donor substrate 300. However, in the method of manufacturing a display device according to an exemplary embodiment of the present disclosure, the plurality of first LEDs 130, the plurality of second LEDs 140, and the plurality of third LEDs 150 are transferred onto the same donor substrate 300. Also, the second alignment keys AK2 transferred together with the plurality of first LEDs 130 are already disposed on the donor substrate 300. Thus, the second alignment keys AK2 and the third alignment key AK3 of the second wafer 220 or the third wafer 230 may not be transferred onto the donor substrate 300. Therefore, the process time for transferring the second alignment keys AK2 and the third alignment key AK3 may be reduced.

Meanwhile, by using the plurality of second alignment keys AK2 transferred onto the donor substrate 300 and the third alignment key AK3 of the second wafer 220 as a reference for aligning the second wafer 220 and the donor substrate 300, the alignment accuracy of the plurality of LEDs ED may be improved.

Accordingly, referring to FIG. 7G, the alignment between the second wafer 220 and the donor substrate 300 is completed, and then, the second wafer 220 may be shifted by a first interval IN1 (e.g., a first distance). The first interval IN1 is equal to an interval between the plurality of sub pixels SP disposed on the second wafer 220. That is, after the second wafer 220 is shifted by the interval between a pair of sub pixels from the plurality of sub pixels SP, the plurality of second LEDs 140 is transferred onto the donor substrate 300.

If the second wafer 220 is not shifted and a laser is irradiated to the same position in the second wafer 220 as that in the first wafer 210, the plurality of second LEDs 140 may be transferred onto the protrusions 331 on which the plurality of first LEDs 130 are disposed. Also, the plurality of first LEDs 130 may interfere with the plurality of second LEDs 140. Accordingly, after the second wafer 220 is shifted by the first interval IN1 which is the interval between the sub pixels SP, a laser may be irradiated to the second wafer 220 to transfer the plurality of second LEDs 140 onto the donor substrate 300 without the third alignment keys AK3 of the second wafer 220 being transferred onto the donor substrate 300. Further, the second LED 140 irradiated with the laser may be detached from the second wafer 220 and attached to the plurality of protrusions 331 of the donor substrate 300.

Referring to FIG. 7H, the plurality of second LEDs 140 may be transferred onto the protrusions 331 at positions corresponding to the third sub pixel SP3 among the plurality of protrusions 331 of the donor substrate 300. The plurality of second LEDs 140 may be LEDs ED disposed in the third sub pixel SP3. Thus, the plurality of second LEDs 140 may be transferred only onto some protrusions 331 to be aligned corresponding to the third sub pixel SP3 among the plurality of protrusions 331 disposed corresponding to the plurality of sub pixels SP.

After the plurality of second LEDs 140 of the second wafer 220 are transferred onto the donor substrate 300, the second wafer 220 and the donor substrate 300 are detached (S123). Then, the donor substrate 300 onto which the second LEDs 140 are transferred is discharged from the process equipment (S124).

Thereafter, the donor substrate 300 on which the first LEDs 130 and the second LEDs 140 are disposed and the third wafer 230 on which a plurality of third LEDs 150 are formed are put into the process equipment (S130). Then, the third wafer 230 is aligned with the donor substrate 300 (S131).

Referring to FIG. 7I, in a state where the third wafer 230 and the donor substrate 300 are disposed such that the plurality of third LEDs 150 on the third wafer 230 and the plurality of protrusions 331 of the donor substrate 300 face each other, the third wafer 230 may be aligned with the donor substrate 300.

In this case, the first wafer 210 is aligned with the donor substrate 300 based on the first alignment key AK1 and the first alignment protrusion 333. However, the third wafer 230 may be aligned with the donor substrate 300 based on some second alignment keys AK2 used as a reference for alignment with the second wafer 220 among the plurality of second alignment keys AK2 transferred onto the donor substrate 300 from the first wafer 210.

Specifically, when the donor substrate 300 on which the plurality of first LEDs 130, the plurality of second alignment keys AK2, and the plurality of second LEDs 140 are disposed is aligned with the third wafer 230, the third wafer 230 may be aligned with the donor substrate 300 based on the second alignment key AK2 used for alignment with the second wafer 220 among the plurality of second alignment keys AK2 of the donor substrate 300. For example, the third wafer 230 may be aligned with the donor substrate 300 based on the second alignment key AK2 of the first wafer 210 used for alignment with the second wafer 220 and the third alignment key AK3 of the third wafer 230.

Referring to FIG. 7J, after the alignment between the third wafer 230 and the donor substrate 300 is completed, the third wafer 230 may be shifted by a second interval IN2 that is greater than the first interval IN1. In one embodiment, the second interval IN2 is twice the first interval IN1. After the third wafer 230 is shifted by the second interval IN2, the plurality of third LEDs 150 are transferred onto the donor substrate 300. Thus, the third wafer 230 may be shifted by the first interval IN1 twice, i.e., a second interval IN2 which is twice the first interval IN1, in order to suppress interference with the plurality of first LEDs 130 and the plurality of second LEDs 140 on the donor substrate 300. Finally, after the third wafer 230 is shifted by the second interval IN2 in the same direction as the shifted direction of the second wafer 220, the plurality of third LEDs 150 are transferred onto the donor substrate 300 without the third alignment keys AK3 of the third wafter 230 being transferred onto the donor substrate 300.

Referring to FIG. 7L and FIG. 7K, the plurality of third LEDs 150 are transferred onto the donor substrate 300 (S132). The plurality of third LEDs 150 may be transferred onto the protrusions 331 at positions corresponding to the fourth sub pixels SP4 among the plurality of protrusions 331 of the donor substrate 300. The plurality of third LEDs 150 may be LEDs ED disposed in the fourth sub pixel SP4. Thus, the plurality of third LEDs 150 may be transferred only onto some protrusions 331 to be aligned corresponding to the fourth sub pixel SP4 among the plurality of protrusions 331 disposed corresponding to the plurality of sub pixels SP.

The plurality of first LEDs 130, the plurality of second LEDs 140, and the plurality of third LEDs 150 may be disposed on the donor substrate 300 at the first interval IN1 which is the interval between the plurality of sub pixels SP. For example, even if the plurality of first LEDs 130 and the plurality of second alignment keys AK2 are disposed to deviate from the centers of upper surfaces of the plurality of protrusions 331 and the plurality of second alignment protrusions 334, the plurality of second LEDs 140 and the plurality of third LEDs 150 to be transferred thereafter are transferred based on the second alignment keys AK2 disposed at a predetermined interval from the plurality of first LEDs 130. Therefore, the plurality of second LEDs 140 and the plurality of third LEDs 150 may be disposed to deviate on the plurality of protrusions 331 in the same manner as the plurality of first LEDs 130. Also, relative positions among the plurality of first LEDs 130, the plurality of second LEDs 140, and the plurality of third LEDs 150 may be easily aligned. Accordingly, the relative positions among the plurality of first LEDs 130, the plurality of second LEDs 140, and the plurality of third LEDs 150 on the donor substrate 300 may correspond to the plurality of sub pixels SP.

After the plurality of third LEDs 150 of the third wafer 230 are transferred onto the donor substrate 300, the third wafer 230 and the donor substrate 300 are detached (S133) and the donor substrate 300 onto which the third LEDs 150 are transferred is discharged from the process equipment (S134).

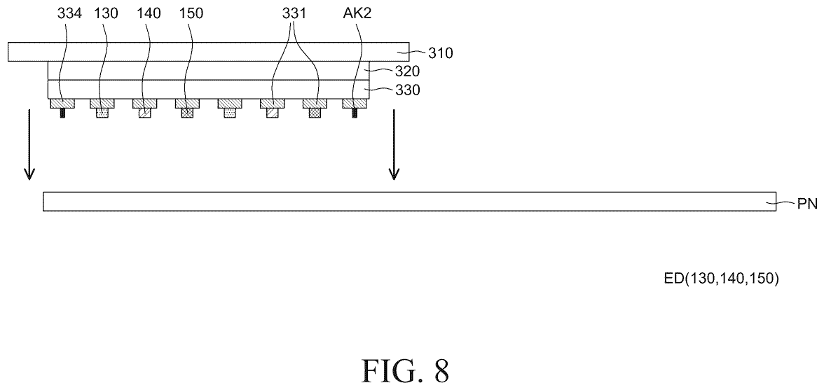

Hereinafter, a secondary transfer process by which the plurality of LEDs ED of the donor substrate 300 is transferred onto the display panel PN will be described with reference to FIG. 8.

FIG. 8 is a process diagram for explaining the method of manufacturing a display device according to an exemplary embodiment of the present disclosure. Specifically, FIG. 8 is a schematic process diagram for explaining the secondary transfer process by which the plurality of LEDs ED on the donor substrate 300 is transferred onto the display panel PN.

Referring to FIG. 8, the secondary transfer process may be performed to transfer the plurality of LEDs ED on the donor substrate 300 onto the display panel PN. Accordingly, the manufacturing process of the display device 100 may be completed. In this case, a circuit, e.g., the driving transistor DT and a plurality of lines, for driving the plurality of LEDs ED has been formed on the display panel PN.

The plurality of first LEDs 130, the plurality of second LEDs 140, and the plurality of third LEDs 150 on the donor substrate 300 are disposed at the same interval in the same array as the plurality of sub pixels SP. Since the plurality of first LEDs 130, the plurality of second LEDs 140, and the plurality of third LEDs 150 on the donor substrate 300 are disposed at the same interval in the same array as the plurality of sub pixels SP, the plurality of first LEDs 130, the plurality of second LEDs 140, and the plurality of third LEDs 150 of the donor substrate 300 may be transferred onto the display panel PN at a same time.

First, the donor substrate 300 on which the plurality of first LEDs 130, the plurality of second LEDs 140, and the plurality of third LEDs 150 are disposed and the display panel PN are put into the process equipment. Then, the donor substrate 300 is aligned with the display panel PN.

In this case, the donor substrate 300 may be aligned with the display panel PN based on the second alignment key AK2 of the first wafer 210 used for alignment with the second wafer 220 and the third wafer 230 of the donor substrate 300 and an alignment key of the display panel PN. The plurality of second LEDs 140 and the plurality of third LEDs 150 disposed on the donor substrate 300 are transferred not based on the first alignment protrusion 333 of the donor substrate 300, but based on the second alignment key AK2 transferred onto the donor substrate 300 from the first wafer 210. That is, an interval between the second alignment key AK2 and the plurality of first LEDs 130 is constant, and an interval of the plurality of second LEDs 140 and the plurality of third LEDs 150, which are transferred onto the donor substrate 300 based on the second alignment key AK2, from the second alignment key AK2 may also be constant. Accordingly, the plurality of LEDs ED may be easily transferred corresponding to the plurality of sub pixels SP of the display panel PN only when the display panel PN is aligned with the donor substrate 300 based on the second alignment key AK2.

If the donor substrate 300 is aligned with the display panel PN based on another component of the donor substrate 300, the plurality of second LEDs 140 and the plurality of third LEDs 150 may have various intervals from the other component. Therefore, the plurality of second LEDs 140 and the plurality of third LEDs 150 may not be transferred to their correct positions when transferred onto the display panel PN. For example, when the donor substrate 300 is aligned with the display panel PN based on the first alignment protrusion 333 of the donor substrate 300, the centers of the upper surfaces of the plurality of protrusions 331 may be aligned corresponding to the plurality of sub pixels SP. However, if the donor substrate 300 is aligned with the display panel PN based on the first alignment protrusion 333 when the plurality of first LEDs 130, the plurality of second LEDs 140, and the plurality of third LEDs 150 are disposed on the donor substrate 300 so as to be spaced apart from the centers of the upper surfaces of the plurality of protrusions 331, it may be difficult to transfer the plurality of LEDs ED of the donor substrate 300 to their correct positions in the display panel PN.

Therefore, if the donor substrate 300 is aligned with the display panel PN based on the second alignment key AK2, which is a reference for aligning relative positions of the plurality of first LEDs 130, the plurality of second LEDs 140, and the plurality of third LEDs 150 and has a constant interval from the plurality of LEDs ED, the alignment accuracy for transferring the plurality of LEDs ED to the correct positions may be improved. Therefore, when the plurality of first LEDs 130, the plurality of second LEDs 140, and the plurality of third LEDs 150 of the donor substrate 300 are transferred onto the display panel PN, the donor substrate 300 may be aligned with the display panel PN based on the second alignment key AK2 used for alignment with the second wafer 220 and the third wafer 230.

The alignment key of the display panel PN to be aligned with the second alignment key AK2 on the donor substrate 300 may be any one of the components formed on the display panel PN, or may be separately formed and disposed. For example, if the alignment key is any one of the components formed on the display panel PN, a reflective layer overlapping the plurality of LEDs ED or some of the plurality of lines for driving the plurality of LEDs ED among the components formed on the display panel PN may also serve as the alignment key. Further, if the alignment key is separately formed and disposed, the alignment key may be a pattern or structure formed on the display panel PN, but is not limited thereto.

Then, after the alignment between the donor substrate 300 and the display panel PN is completed, the plurality of first LEDs 130, the plurality of second LEDs 140, and the plurality of third LEDs 150 are transferred onto the display panel PN. Further, after the plurality of LEDs ED of the donor substrate 300 is transferred onto the display panel PN, the donor substrate 300 and the display panel PN are detached and the donor substrate 300 and the display panel PN are discharged from the process equipment.

Therefore, through the primary transfer process of transferring the plurality of LEDs ED onto the donor substrate 300 from the wafer 200 and the secondarily transfer process of transferring the plurality of LEDs ED, which has been transferred onto the donor substrate 300, onto the display panel PN, the manufacturing process of the display device 100 may be completed.

Meanwhile, in the method of manufacturing the display device 100 according to an exemplary embodiment of the present disclosure, the plurality of first LEDs 130, the plurality of second LEDs 140, and the plurality of third LEDs 150 may have the first interval IN1 when transferred to one donor substrate 300 in order to transfer the plurality of first LEDs 130, the plurality of second LEDs 140, and the plurality of third LEDs 150 onto the display panel PN at a time. In this case, as described above, the plurality of protrusions 331 may have a greater size than the plurality of LEDs ED in consideration of an alignment error between the wafer 200 and the donor substrate 300. When the first wafer 210 is aligned with the donor substrate 300, the plurality of first LEDs 130 transferred onto the plurality of protrusions 331 may be disposed to deviate from the centers of the upper surfaces of the plurality of protrusions 331 due to an alignment error between the first alignment key AK1 and the first alignment protrusion 333. In this case, even if the second wafer 220 is aligned with the donor substrate 300 again based on the first alignment key AK1 of the second wafer 220 and the first alignment protrusion 333 of the donor substrate 300 and the plurality of second LEDs 140 transferred onto the plurality of protrusions 331 is disposed at their correct positions, an interval between the plurality of first LEDs 130 and the plurality of second LEDs 140 may be different from the first interval IN1. Therefore, the alignment accuracy may decrease.

Accordingly, when the second wafer 220 is aligned with the donor substrate 300, they are aligned based on the second alignment key AK2 disposed at a predetermined interval from the first LED 130. Thus, the plurality of second LEDs 140 may be transferred while maintaining the relative position between the plurality of first LEDs 130 and the plurality of second LEDs 140 transferred onto the donor substrate 300, i.e., the first interval IN1 between the plurality of first LEDs 130 and the plurality of second LEDs 140. Therefore, the alignment accuracy may be improved.

Also, when the second wafer 220 and the third wafer 230 are aligned with the donor substrate 300, they may be aligned based on the second alignment key AK2 disposed at a predetermined interval from the first LED 130 and transferred onto the donor substrate 300 from the first wafer 210. Therefore, the alignment accuracy may be improved.

In the display device 100 according to an exemplary embodiment of the present disclosure, a relative position with respect to the other LEDs ED to be transferred onto the donor substrate 300 is aligned based on the second alignment key AK2 transferred together with the plurality of LEDs ED in the primary transfer process and maintaining the same interval from the plurality of LEDs ED. Thus, an alignment error range of the plurality of LEDs ED may be reduced. Therefore, the alignment accuracy may be improved. Specifically, after the plurality of first LEDs 130 and the plurality of second alignment keys AK2 are transferred together onto the donor substrate 300, the second wafer 220 and the third wafer 230 may be aligned with the donor substrate 300 based on the plurality of second alignment keys AK2. Even in the secondary transfer process, the donor substrate 300 may be aligned with the display panel PN based on the same second alignment key AK2. The second alignment key AK2 as well as the plurality of first LEDs 130 transferred onto the donor substrate 300 may maintain the same interval from each of the plurality of first LEDs 130. Accordingly, when the second wafer 220 and the third wafer 230 are aligned with the donor substrate 300 based on the second alignment key AK2, a relative position may be aligned in order for the plurality of second LEDs 140 of the second wafer 220 and the plurality of first LEDs 130 of the donor substrate 300 to have the first interval IN1. Accordingly, an alignment error range and a distribution/spread of the plurality of first LEDs 130 serving as a reference in the primary transfer process may be eliminated. Further, even in the secondary transfer process, the second alignment key AK2, which has served as a reference for alignment of the plurality of first LEDs 130, the plurality of second LEDs 140, and the plurality of third LEDs 150, is used as a reference. Thus, it is possible to minimize or at least reduce an alignment error range and a distribution/spread of the plurality of first LEDs 130, the plurality of second LEDs 140, and the plurality of third LEDs 150.

When the display device 100 is manufactured by transferring the plurality of LEDs ED, which has been transferred onto the donor substrate 300, onto the display panel PN, productivity and yield may be improved by forming an integrated donor substrate 300 on which the plurality of LEDs ED is transferred corresponding to the plurality of sub-pixels, respectively. For example, the plurality of first LEDs 130, the plurality of second LEDs 140, and the plurality of third LEDs 150 may be primarily transferred onto one donor substrate 300 so as to correspond to the plurality of sub-pixels SP, respectively. Then, the plurality of first LEDs 130, the plurality of second LEDs 140, and the plurality of third LEDs 150 disposed on the donor substrate 300 may be transferred onto the display panel PN at a time. Accordingly, the display device 100 may be manufactured.

Conventionally, after the first wafer 210 is aligned with the donor substrate 300 by aligning the first alignment key AK1 of the first wafer 210 with the first alignment protrusion 333 of the donor substrate 300, the second alignment key AK2 is transferred onto the donor substrate 300 together with the first LED 130. Then, the second wafer 220, the donor substrate 300, and the third wafer 230 are aligned with the donor substrate 300 based on the second alignment key AK2 disposed on the donor substrate 300 and some of the components of the second wafer 220 and the third wafer 230.

For example, the donor substrate 300 may be aligned with the second wafer 220 based on the second alignment key AK2 disposed on the donor substrate 300 and the second LED 140 of the second wafer 220. Also, the donor substrate 300 may be aligned with the third wafer 230 based on the second alignment key AK2 disposed on the donor substrate 300 and the third LED 150 of the third wafer 230. However, the second alignment key AK2 transferred onto the donor substrate 300 may be formed regardless of the second LED 140 of the second wafer 220. Thus, the alignment accuracy of the donor substrate 300 and the second wafer 220 may decrease. For example, the second alignment key AK2 may be different in size and shape from the second LED 140. Accordingly, it may be difficult to align the center of the second alignment key AK2 with the center of an upper surface of the second LED 140. Therefore, the alignment accuracy of the donor substrate 300 and the second wafer 220 may decrease. Also, even when the donor substrate 300 is aligned with the third wafer 230 based on the second alignment key AK2 disposed on the donor substrate 300 and the third LED 150 of the third wafer 230, the second alignment key AK2 may be different in size and shape from the third LED 150. Therefore, the alignment accuracy of the donor substrate 300 and the third wafer 230 may decrease.

Accordingly, the donor substrate 300 may be aligned with the second wafer 220 and the third wafer 230 based on the second alignment key AK2 disposed on the donor substrate 300 and the first alignment keys AK1 of the second wafer 220 and the third wafer 230. However, the first alignment key AK1 is disposed corresponding to the first alignment protrusion 333 regardless of the second alignment key AK2 to align the donor substrate 300 with the first wafer 210. Accordingly, the alignment accuracy between the donor substrate 300 and the second wafer 220 and the alignment accuracy between the donor substrate 300 and the third wafer 230 may decrease.

Accordingly, the donor substrate 300 may be aligned with the second wafer 220 and the third wafer 230 based on the second alignment key AK2 disposed on the donor substrate 300 and the second alignment keys AK2 of the second wafer 220 and the third wafer 230. However, the second alignment key AK2 disposed on the donor substrate 300 is disposed with the same shape and the same size as the second alignment keys AK2 disposed on the second wafer 220 and the third wafer 230. It may be difficult to align the centers thereof. Accordingly, the alignment accuracy between the donor substrate 300 and the second wafer 220 and the alignment accuracy between the donor substrate 300 and the third wafer 230 may decrease.

Accordingly, the donor substrate 300 may be aligned with the second wafer 220 and the third wafer 230 based on the second alignment protrusion 334 disposed on the donor substrate 300 and the first alignment keys AK1 of the second wafer 220 and the third wafer 230. However, the second alignment protrusion 334 may be changed in position while the first wafer 210 is aligned with the donor substrate 300. For example, the resin layer 330 and the plurality of protrusions 331 of the donor substrate 300 may be made of a polymer material having viscoelasticity. Thus, in the transfer process, the positions or shapes of the plurality of protrusions 331 may be changed by an impact applied to the donor substrate 300. Accordingly, the second alignment key AK2 may be changed in position on the second alignment protrusion 334 and then transferred. In particular, an alignment error range and a distribution/spread may gradually increase from a central portion of the donor substrate 300. Thus, when the donor substrate 300 is aligned with the second wafer 220 and the third wafer 230 based on the second alignment key AK2 transferred onto the donor substrate 300, the alignment and transfer accuracy of the plurality of LEDs ED may decrease.

Accordingly, in the method of manufacturing a display device according to an exemplary embodiment of the present disclosure, the first alignment key AK1, the second alignment key AK2, and the third alignment key AK3 including a hole corresponding in size to the second alignment key AK2 is disposed on the wafer 200. Also, alignment and transfer are performed based on the second alignment key AK2 disposed on the donor substrate 300, the third alignment key AK3 of the second wafer 220, and the third alignment key AK3 of the third wafer 230. Therefore, it is possible to precisely align a relative position between the plurality of first LEDs 130 of the donor substrate 300 and the plurality of second LEDs 140 of the second wafer 220 and a relative position between the plurality of first LEDs 130 of the donor substrate 300 and the plurality of third LEDs 150 of the third wafer 230 based on the third alignment keys AK3 fixed to the second wafer 220 and the third wafer 230. Further, each of the plurality of third alignment keys AK3 includes a hole corresponding in size to the second alignment key AK2. Thus, it is possible to precisely align the second alignment key AK2 disposed on the donor substrate 300 with the third alignment keys AK3 disposed on the second wafer 220 and the second wafer 220.

The exemplary embodiments of the present disclosure can also be described as follows:

According to an aspect of the present disclosure, there is provided a method of manufacturing a display device. The method of manufacturing the display device comprises a process of aligning, with a donor substrate, a first wafer on which a plurality of first light emitting diodes (LEDs), a plurality of first alignment keys, and a plurality of second alignment keys are disposed. The method of manufacturing the display device comprises a process of transferring, onto the donor substrate, the plurality of first LEDs and some of the second alignment keys on the first wafer. The method of manufacturing the display device comprises a process of aligning, with the donor substrate, a second wafer on which a plurality of second LEDs, a plurality of first alignment keys, a plurality of second alignment keys, and a plurality of third alignment keys are disposed, wherein the process of aligning the second wafer with the donor substrate includes a process of performing alignment based on some of the plurality of second alignment keys of the first wafer disposed on the donor substrate and the plurality of third alignment keys of the second wafer.

The plurality of second alignment keys of the first wafer may correspond in shape to the plurality of third alignment keys of the second wafer, respectively.

The process of aligning the second wafer with the donor substrate may further include a process of shifting the second wafer by a predetermined interval after the process of performing alignment based on some of the plurality of second alignment keys of the first wafer disposed on the donor substrate and the plurality of third alignment keys of the second wafer.

The method of manufacturing the display device may further comprise a process of transferring the plurality of second LEDs onto the donor substrate on which the plurality of first LEDs is disposed. The method of manufacturing the display device may further comprise a process of aligning, with the donor substrate, a third wafer on which a plurality of third LEDs, a plurality of first alignment keys, a plurality of second alignment keys, and a plurality of third alignment keys are disposed. The method of manufacturing the display device may further comprise a process of transferring the plurality of third LEDs onto the donor substrate on which the plurality of first LEDs and the plurality of second LEDs are disposed. The process of aligning the third wafer with the donor substrate may include a process of performing alignment based on some of the plurality of second alignment keys of the first wafer disposed on the donor substrate and the plurality of third alignment keys of the third wafer.

The process of aligning the third wafer with the donor substrate may further include a process of shifting the third wafer by a predetermined interval after the process of performing alignment based on some of the plurality of second alignment keys of the first wafer disposed on the donor substrate and the plurality of third alignment keys of the third wafer.

The method of manufacturing the display device may further comprise a process of aligning, with a display panel, the donor substrate on which the plurality of first LEDs, the plurality of second LEDs, and the plurality of third LEDs are disposed, based on some of the plurality of second alignment keys of the first wafer disposed on the donor substrate. The method of manufacturing the display device may further comprise a process of transferring, onto the display panel, the plurality of first LEDs, the plurality of second LEDs, and the plurality of third LEDs on the donor substrate.

According to an aspect of the present disclosure, there is provided a wafer. The wafer that includes an active area and a peripheral area enclosing the active area, may comprise a plurality of LEDs disposed in the active area, and a plurality of alignment keys disposed in the peripheral area wherein the plurality of alignment keys includes a plurality of first alignment keys, a plurality of second alignment keys, and a plurality of third alignment keys which have different shapes from one another.

One of the plurality of first alignment keys and one of the plurality of third alignment keys may be disposed in each of four regions corresponding to edges of the active area. The plurality of second alignment keys may be disposed in each of the four regions corresponding to the edges of the active area. In each of the four regions, an interval between the third alignment key and one of the plurality of second alignment keys located at a corresponding position may be constant.

The plurality of third alignment keys may correspond in shape to the plurality of second alignment keys, respectively.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A method of manufacturing a display device, comprising:
aligning a first wafer with a donor substrate, the first wafer including a plurality of first light emitting diodes (LEDs), a plurality of first alignment keys, and a plurality of second alignment keys;
transferring the plurality of first LEDs and a portion of the plurality of second alignment keys included in the first wafer onto the donor substrate; and
aligning a second wafer with the donor substrate, the second wafer including a plurality of second LEDs, a plurality of first alignment keys, a plurality of second alignment keys, and a plurality of third alignment keys,
wherein the second wafer is aligned with the donor substrate by aligning the portion the plurality of second alignment keys of the first wafer that are disposed on the donor substrate with the plurality of third alignment keys of the second wafer.

2. The method of manufacturing the display device according to claim 1, wherein a shape of the plurality of second alignment keys of the first wafer corresponds to a shape of the plurality of third alignment keys of the second wafer.

3. The method of manufacturing the display device according to claim 1, wherein aligning the second wafer with the donor substrate further comprises:
shifting the second wafer by a first predetermined interval after the portion the plurality of second alignment keys of the first wafer that are disposed on the donor substrate are aligned with the plurality of third alignment keys of the second wafer.

4. The method of manufacturing the display device according to claim 3, further comprising:
transferring the plurality of second LEDs onto the donor substrate on which the plurality of first LEDs are disposed;
aligning a third wafer with the donor substrate, the third wafer including a plurality of third LEDs, a plurality of first alignment keys, a plurality of second alignment keys, and a plurality of third alignment keys; and
transferring the plurality of third LEDs onto the donor substrate on which the plurality of first LEDs and the plurality of second LEDs are disposed,
wherein the third wafer is aligned with the donor substrate by aligning the portion of the plurality of second alignment keys of the first wafer that are disposed on the donor substrate with the plurality of third alignment keys of the third wafer.

5. The method of manufacturing the display device according to claim 4, wherein aligning the third wafer with the donor substrate further comprises:
shifting the third wafer by a second predetermined interval after the portion of the plurality of second alignment keys of the first wafer that are disposed on the donor substrate are aligned with the plurality of third alignment keys of the third wafer, the second predetermined interval greater than the first predetermined interval.

6. The method of manufacturing the display device according to claim 4, further comprising:
aligning the donor substrate that includes the plurality of first LEDs, the plurality of second LEDs, and the plurality of third LEDs with a display panel by aligning the portion of the plurality of second alignment keys of the first wafer that are disposed on the donor substrate and an alignment key included in the display panel; and
transferring the plurality of first LEDs, the plurality of second LEDs, and the plurality of third LEDs on the donor substrate onto the display panel after aligning the donor substrate and the display panel.

7. A wafer comprising:
an active area and a peripheral area enclosing the active area;
a plurality of light emitting diodes (LEDs) in the active area but not the peripheral area; and
a plurality of alignment keys in the peripheral area but not the active area, the plurality of alignment keys including a plurality of first alignment keys having a first size, a plurality of second alignment keys having a second size that is different from the first size, and a plurality of third alignment keys having a third size that is different from the first size and the second size.

8. The wafer according to claim 7, wherein one of the plurality of first alignment keys and one of the plurality of third alignment keys are disposed in each of a plurality of regions corresponding to edges of the active area and a subset of second alignment keys from the plurality of second alignment keys is disposed in each of the plurality of regions corresponding to the edges of the active area, and
in each region of the plurality of regions, an interval between the third alignment key and one of the plurality of second alignment keys in the region is a same across the plurality of regions.

9. The wafer according to claim 7, wherein a shape of the plurality of third alignment keys corresponds to a shape of the plurality of second alignment keys.

10. The wafer according to claim 9, wherein each second alignment key from the plurality of second alignment keys has a circular shape and each third alignment key from the plurality of third alignment keys has a ring shape, and the second alignment key having the circular shape fits within the third alignment key having the ring shape.

11. The wafer according to claim 9, wherein each second alignment key from the plurality of second alignment keys has a “+” shape and each third alignment key from the plurality of third alignment keys has a “x” shape, and a center of the “+” shape of the second alignment key aligns with a center of the “x” shape of the third alignment key.

12. The wafer according to claim 7, wherein the plurality of first alignment keys are configured to be aligned with a plurality of alignment protrusions on a donor substrate.

13. The wafer according to claim 12, wherein a subset of the plurality of second alignment keys is configured to be transferred from the wafer to the donor substrate along with the plurality of LEDs.

14. A method of manufacturing a display device comprising:
placing a first wafer over a donor substrate, the first wafer including a plurality of first light emitting diodes (LEDs) that are configured to emit a first color of light, a plurality of first alignment keys, and a plurality of second alignment keys, and the donor substrate including a plurality of first alignment protrusions and a plurality of second alignment protrusions;
aligning each of the plurality of first alignment keys of the first wafer with a corresponding first alignment protrusion from the plurality of first alignment protrusions;
transferring the plurality of first LEDs and a subset of the plurality of second alignment keys included in the first wafer onto the donor substrate after the alignment of each of the plurality of first alignment keys of the first wafer with the corresponding first alignment protrusion from the plurality of first protrusions, the subset of the plurality of second alignment keys transferred to the plurality of second alignment protrusions on the donor substrate;
placing a second wafer over the donor substrate including the plurality of first LEDs and the subset of the plurality of second alignment keys from the first wafer, the second wafer including a plurality of second LEDs that are configured to emit a second color of light that is different from the first color of light and a plurality of alignment keys;
aligning each second alignment key from the subset of the plurality of second alignment keys that were transferred from the first wafer to the donor substrate with a corresponding one of the plurality of alignment keys of the second wafer;
shifting the second wafer by a first interval that corresponds to a distance between a pair of second LEDs from the plurality of second LEDs on the second wafer after aligning each second alignment key with the corresponding one of the plurality of alignment keys of the second wafer; and
transferring the plurality of second LEDs onto the donor substrate without transferring any of the plurality of alignment keys of the second wafer onto the donor substrate after shifting the second wafer by the first interval.

15. The method according to claim 14, wherein a shape of the plurality of second alignment keys of the first wafer corresponds to a shape of the plurality of alignment keys of the second wafer.

16. The method according to claim 15, wherein each second alignment key from the plurality of second alignment keys of the first wafer has a circular shape and each alignment key from the plurality of alignment keys of the second wafer has a ring shape, and aligning each second alignment key comprises:
aligning a center of each second alignment key having the circular shape with a center of a hole in the corresponding alignment key from the second wafer having the ring shape.

17. The method according to claim 15, wherein each second alignment key from the plurality of second alignment keys of the first wafer has a “+” shape and each alignment key from the plurality of alignment keys from the second wafer has a “x” shape, and aligning each second alignment key comprises:
aligning a center of each second alignment key having the “+” shape with a center of the corresponding alignment key of the second wafer having the “x” shape.

18. The method according to claim 14, further comprising:
placing a third wafer over the donor substrate including the plurality of first LEDs, the plurality of second LEDs, and the subset of the plurality of second alignment keys from the first wafer, the third wafer including a plurality of third LEDs that are configured to emit a third color of light that is different from the first color of light and the second color of light and a plurality of alignment keys of the third wafer;
aligning each second alignment key from the subset of plurality of second alignment keys that were transferred from the first wafer to the donor substrate with a corresponding one of the plurality of alignment keys of the third wafer;
shifting the third wafer by a second interval that is greater than the first interval after aligning each second alignment key with the corresponding one of the plurality of alignment keys of the third wafer; and
transferring the plurality of third LEDs onto the donor substrate without transferring any of the plurality of alignment keys of the third wafer onto the donor substrate after shifting the second wafer by the second interval.

19. The method according to claim 18, wherein the second interval is twice the first interval.

20. The method according to claim 18, further comprising:
aligning the donor substrate that includes the plurality of first LEDs, the plurality of second LEDs, and the plurality of third LEDs with a display panel by aligning the subset of the plurality of second alignment keys of the first wafer that are disposed on the donor substrate and an alignment key included in the display panel; and
transferring the plurality of first LEDs, the plurality of second LEDs, and the plurality of third LEDs on the donor substrate onto the display panel after aligning the donor substrate and the display panel.
